(19) United States
(12) Patent Application Publication
(10) Pub. No.: US 2004/0152336 A1
(43) Pub. Date: Aug. 5, 2004

(54) Semiconductor device and its manufacturing method

(75) Inventors: Noriko Miura, Itami (JP); Kazutoshi Ohmori, Higashihiroshima (JP); Kiyohiko Sato, Ome (JP); Junji Noguchi, Tokyo (JP); Tsuyoshi Tamaru, Hachioji (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 10/752,043

(22) Filed: Jan. 7, 2004

(30) Foreign Application Priority Data
Jan. 8, 2003 (JP) P2003-002529

(51) Int. Cl. H01L 21/31

(52) U.S. Cl. 438/761

(57) ABSTRACT

Disclosed here is a method for manufacturing a semiconductor device, which can prevent films from delamination and improve the reliability of the semiconductor. A first insulating film comprising a silicon carbide film, silicon carbide nitride film, or silicon oxide nitride film is formed as a barrier insulating film of the wiring, and then a second insulating film comprising a fluorine containing silicon oxide film is formed on the first insulating film by a high density plasma CVD method as a low permittivity insulating film. And, when forming the second insulating film, the semiconductor substrate is heated up to a predetermined deposition temperature using a heat-up plasma generated by a gas containing no oxygen such as an argon plasma. When the substrate reaches the predetermined deposition temperature, the insulating film deposition gas is introduced into the deposition chamber to deposit the second insulating film on the first insulating film. Consequently, the surface of the first insulating film is suppressed from oxidization, thereby the adhesion that functions between the first and second insulating films is improved.

### FIELD OF THE INVENTION

The present invention relates to a semiconductor device and its manufacturing method, more particularly to a technique applicable effectively for manufacturing techniques of semiconductor devices.

### BACKGROUND OF THE INVENTION

A semiconductor device circuit usually employs a multi-layer wiring structure that connects an element to another therein. The wiring pitch between circuit elements has been narrowed more and more due to the progress of the high density integration technique developed for semiconductor devices. Consequently, the parasitic capacity between wirings comes to increase, resulting in signal delay. And, to avoid this, reduction of the parasitic capacity between wirings has been expected. Using a low permittivity material as an inter-wiring insulating film is one of such methods for reducing the parasitic capacity between wirings. The low permittivity material to be used as an insulating film between layers is, for example, a fluorine-containing silicon oxide film (refer to the patent documents 1 and 2).

Furthermore, an embedded copper wiring structure to be employed as a wiring structure of refined semiconductor devices is now under development. In the embedded copper wiring structure, a wiring material is embedded in such wiring apertures as wiring grooves and holes formed, for example, in an insulating film by a damascene technique, a single-damascene technique, and a dual-damascene technique. In addition, in the embedded copper wiring structure, a silicon nitride film or the like is formed on a copper wiring embedded insulating film so as to cover the top surface of the copper wiring and used as a barrier insulating film for preventing diffusion of the copper of the wiring. And, the dual-damascene technique uses a silicon nitride film or the like as an etching stopper film.

[Patent Document 1]

Official gazette of JP-A No. 148562/1996

[Patent Document 2]

Official gazette of JP-A No. 317454/1999

The inter-wiring capacity described above can be reduced more effectively if an insulating film of which permittivity is lower than that of the silicon nitride film is used as a barrier insulating film and/or etching stopper film. And, in that connection, the operation speed of the subject semiconductor device is improved. This is why it would be proper to use a silicon carbide film, a silicon carbide nitride film, or the like having a lower permittivity than that of the silicon nitride film as a barrier insulating film and/or etching stopper film described above.

According to the examination conducted by the inventor of the present invention, it is found that if a silicon carbide film, silicon carbide nitride film, or the like is formed as a barrier insulating film and/or etching stopper film, then a fluorine-containing silicon oxide film is formed on the barrier insulating film/etching stopper film as a low permittivity inter-layer, those films are often delaminated from each other easily. And, this causes the reliability of the semiconductor device to be lowered and the manufacturing yield of the semiconductor devices to be lowered.

Under such circumstances, it is an object of the present invention to provide a semiconductor device and its manufacturing method that can prevent films from such delamination.

It is another object of the present invention to provide a semiconductor device and its manufacturing method that can improve the reliability thereof.

These and other objects and novel features of the present invention will become more apparent as description proceeds when considered with the accompanying drawings.

### SUMMARY OF THE INVENTION

The typical features of the present invention to be disclosed in this specification will be summarized as follows.

The semiconductor device manufacturing method of the present invention heats the semiconductor substrate up to a predetermined film deposition temperature with plasma generated by a gas containing no oxygen in the deposition process of an insulating film comprising fluorine-containing silicon oxide.

Furthermore, the semiconductor device manufacturing method of the present invention forms a silicon oxide film or silicon oxide nitride film between an insulating film comprising a material containing silicon and carbon and a fluorine-containing silicon oxide film in the deposition process of the insulating film and the silicon oxide film.

Furthermore, the semiconductor device manufacturing method of the present invention, when forming a fluorine-containing silicon oxide film, HSQ film, MSQ film, or organic polymer film on an insulating film comprising a material containing silicon and carbon, performs a plasma treatment on the surface of the lower layer insulating film with plasma generated by an inactive gas, then forms the upper layer insulating film.

The semiconductor device of the present invention has a silicon oxide or silicon oxide nitride film between an insulating film comprising a material containing silicon and carbon and a fluorine-containing silicon oxide film.

### BRIEF DESCRIPTION OF THE DRAWINGS

FIG. 1 is a cross sectional view of a major portion of a semiconductor device in a manufacturing process in an embodiment of the present invention;

FIG. 2 is a cross sectional view of a major portion of the semiconductor device in a manufacturing process that follows the process shown in FIG. 1;

FIG. 3 is a cross sectional view of a major portion of the semiconductor device in a manufacturing process that follows the process shown in FIG. 2;

FIG. 4 is a cross sectional view of a major portion of the semiconductor device in a manufacturing process that follows the process shown in FIG. 3;

FIG. 5 is a cross sectional view of a major portion of the semiconductor device in a manufacturing process that follows the process shown in FIG. 4;

FIG. 6 is a cross sectional view of a major portion of the semiconductor device in a manufacturing process that follows the process shown in FIG. 5;

FIG. 7 is a cross sectional view of a major portion of the semiconductor device in a manufacturing process that follows the process shown in FIG. 6;

FIG. 8 is a gas sequence chart of an SiOF film deposition process;

FIG. 9 is a cross sectional view of a major portion of the semiconductor device in a manufacturing process that follows the process shown in FIG. 7;

FIG. 10 is a cross sectional view of a major portion of the semiconductor device in a manufacturing process that follows the process shown in FIG. 9;

FIG. 11 is a cross sectional view of a major portion of the semiconductor device in a manufacturing process that follows the process shown in FIG. 10;

FIG. 12 is a cross sectional view of a major portion of the semiconductor device in a manufacturing process that follows the process shown in FIG. 11;

FIG. 13 is a cross sectional view of a major portion of the semiconductor device in a manufacturing process that follows the process shown in FIG. 12;

FIG. 14 is a cross sectional view of a major portion of the semiconductor device in a manufacturing process that follows the process shown in FIG. 13;

FIG. 15 is a cross sectional view of a major portion of the semiconductor device in a manufacturing process that follows the process shown in FIG. 14;

FIG. 16 is a cross sectional view of a major portion of the semiconductor device in a manufacturing process that follows the process shown in FIG. 15;

FIG. 17 is a cross sectional view of a major portion of the semiconductor device in a manufacturing process that follows the process shown in FIG. 16;

FIG. 18 is a cross sectional view of a major portion of the semiconductor device in a manufacturing process that follows the process shown in FIG. 17;

FIG. 19 is a cross sectional view of a major portion of the semiconductor device in a manufacturing process that follows the process shown in FIG. 18;

FIG. 20 is an illustration of an HDP-CVD apparatus used in another embodiment of the present invention;

FIG. 21 is a cross sectional view of a major portion of a semiconductor device in another embodiment of the present invention;

FIG. 22 is a cross sectional view of the semiconductor device in a manufacturing process that follows the process shown in FIG. 21;

FIG. 23 is a gas sequence chart of the SiCN film deposition process;

FIG. 24 is a cross sectional view of the semiconductor device in a manufacturing process that follows the process shown in FIG. 22;

FIG. 25 is a cross sectional view of the semiconductor device in a manufacturing process that follows the process shown in FIG. 24;

FIG. 26 is a cross sectional view of the semiconductor device in a manufacturing process that follows the process shown in FIG. 25;

FIG. 27 is a cross sectional view of the semiconductor device in a manufacturing process that follows the process shown in FIG. 26;

FIG. 28 is a cross sectional view of a major portion of a semiconductor device in a manufacturing process in still another embodiment of the present invention;

FIG. 29 is a cross sectional view of the semiconductor device in a manufacturing process that follows the process shown in FIG. 28;

FIG. 30 is a cross sectional view of the semiconductor device in a manufacturing process that follows the process shown in FIG. 29;

FIG. 31 is a cross sectional view of the semiconductor device in a manufacturing process that follows the process shown in FIG. 30;

FIG. 32 is a cross sectional view of the semiconductor device in a manufacturing process that follows the process shown in FIG. 31;

FIG. 33 is a cross sectional view of the semiconductor device in a manufacturing process that follows the process shown in FIG. 32;

FIG. 34 is a table for denoting whether or not each SiOF film is delaminated from its adjacent film;

FIG. 35 is a cross sectional view of a major portion of a semiconductor device in a manufacturing process in still another embodiment of the present invention;

FIG. 36 is a cross sectional view of the semiconductor device in a manufacturing process that follows the process shown in FIG. 35;

FIG. 37 is a cross sectional view of the semiconductor device in a manufacturing process that follows the process shown in FIG. 36;

FIG. 38 is a cross sectional view of the semiconductor device in a manufacturing process that follows the process shown in FIG. 37;

FIG. 39 is a cross sectional view of the semiconductor device in a manufacturing process that follows the process shown in FIG. 38;

FIG. 40 is a cross sectional view of the semiconductor device in a manufacturing process that follows the process shown in FIG. 39;

FIG. 41 is a cross sectional view of the semiconductor device in a manufacturing process that follows the process shown in FIG. 40;

FIG. 42 is a cross sectional view of the semiconductor device in a manufacturing process that follows the process shown in FIG. 41;

FIG. 43 is a cross sectional view of a major portion of a semiconductor device in a manufacturing process in still another embodiment of the present invention;

FIG. 44 is a cross sectional view of the semiconductor device in a manufacturing process that follows the process shown in FIG. 43;

FIG. 45 is a cross sectional view of the semiconductor device in a manufacturing process that follows the process shown in FIG. 44;

FIG. 46 is a cross sectional view of the semiconductor device in a manufacturing process that follows the process shown in FIG. 45;

FIG. 47 is a cross sectional view of a major portion of a semiconductor device in a manufacturing process in still another embodiment of the present invention;

FIG. 48 is a cross sectional view of the semiconductor device in a manufacturing process that follows the process shown in FIG. 47;

FIG. 49 is a cross sectional view of the semiconductor device in a manufacturing process that follows the process shown in FIG. 48; and

FIG. 50 is a cross sectional view of the semiconductor device in a manufacturing process that follows the process shown in FIG. 49.

### DETAILED DESCRIPTION OF THE PREFERRED EMBODIMENTS

The description of the present invention to be made below might be divided into some sections or embodiments as needed. Unless otherwise pointed out specifically, however, those sections and embodiments are related with each other; one section/embodiment is related with some or all of the other sections/embodiments in the description of variations, details, supplements, etc.

The number of elements (including a quantity, a value, an amount, a range, etc. with respect to each of those elements) to be described in the following embodiments may be varied freely so that it is increased/decreased unless otherwise pointed out specifically or limited in a specific quantity clearly.

Furthermore, any element (including element steps, etc.) to be described in the following embodiments is not mandatory unless otherwise pointed out specially or considered to be mandatory clearly as fundamentals.

Similarly, a shape, a position, etc. of an element to be described in the following embodiments shall include those approximate or similar to them substantially unless otherwise pointed out specially or not considered to be so principally. This is also true for both values and ranges described above.

In all the drawings accompanying the following embodiments, the same reference numbers and symbols will be used for the same functional items to avoid redundant description.

In each drawing accompanying the following embodiments, a top view might be hatched sometimes so as to make it easier to look at.

Hereunder, the preferred embodiments of the present invention will be described in detail with reference to the accompanying drawings. In all the drawings accompanying the following embodiments, the same reference numerals and symbols will be used for the same functional items to avoid redundant description. In the description of the following embodiments, the same or similar portion will be described just once unless otherwise the description is needed again specially.

First Embodiment

At first, a description will be made for the manufacturing processes of a semiconductor device in the first embodiment of the present invention with reference to the accompanying drawings. FIG. 1 shows a cross sectional view of a major portion of the semiconductor device, which may be an MISFET (Metal Insulating film Semiconductor Field Effect Transistor) in a manufacturing process in the first embodiment of the present invention.

As shown in FIG. 1, an element isolation region 2 is formed on a main surface of a semiconductor substrate (wafer, semiconductor wafer) 1 comprising, for example, p-type single-crystalline silicon having a specific resistance of 1 to 10 Ω·cm. The element isolation region 2 comprises silicon oxide or the like and it is formed by, for example, an STI (Shallow Trench Isolation) method or LOCOS (Local Oxidization of Silicon) method.

After that, a p-type well 3 is formed in a region of the semiconductor substrate 1, in which an n-channel type MISFET is formed. The p-type well 3 is formed, for example, by implanting such impurity ions as boron (B) in the region.

Then, a gate insulating film 4 is formed on the surface of the p-type well 3. The gate insulating film 4 is formed of, for example, a thin silicon oxide film by, for example, a thermal oxidization method.

Then, a gate electrode 5 is formed on the gate insulating film 4 of the p-type well 3 and comes to comprise a polycrystalline silicon film. Concretely, it is formed as follows, for example; at first a polycrystalline silicon film is formed on the semiconductor substrate 1, then such ions as phosphor (P) or the like are implanted in the polycrystalline silicon film to make it a low resistant n-type semiconductor film, which is then patterned by dry-etching.

After that, an n type semiconductor region 6 is formed in the regions at both sides of the gate electrode 5 of the p-type well 3 by implanting such impurity ions as phosphor (P) or the like therein.

After that, a side wall spacer or side wall 7 is formed of, for example, silicon oxide or the like on the side wall of the gate electrode 5. The side wall 7 is formed, for example, by depositing a silicon oxide film on the semiconductor substrate 1, then applying anisotropic etching for the film.

After forming the side wall 7, an n⁺ type semiconductor region 8 (source, drain) is formed, for example, by implanting such impurity ions as phosphor (P) or the like in both of the gate electrode 5 of the p-type well 3 and the regions at both sides of the side wall 7. The n⁺ type semiconductor region 8 has higher impurity density than the n⁻ type semiconductor region 6.

Then, the gate electrode 5 and the surface of the n⁺ type semiconductor region 8 are exposed and a cobalt (Co) film is deposited on the exposed portions, which are then subjected to a thermal treatment to form silicide films 5a and 8a on the surfaces of the gate electrode 5 and the n⁺ type semiconductor region 8 respectively. Both diffusion resistance and contact resistance of the n⁺ type semiconductor region can thus be reduced. After that, the not-reacted cobalt film is removed.

In such a way, an n-channel type MISFET (Metal Insulating film Semiconductor Field Effect Transistor) 9 is formed in the p type well 3.

After that, an insulating film 10 comprising silicon nitride or the like and an insulating film 11 comprising silicon oxide or the like are deposited in order on the semiconductor substrate 1. The insulating films 11 and 10 are then dry-etched sequentially to form contact holes 12 on the top surfaces of the n⁺ type semiconductor region (source, drain) 8, etc. At the bottom of each contact hole 12 are exposed part of the main surface of the semiconductor substrate 1, for example, part of the n⁺ type semiconductor region 8 and part of the gate electrode 5 respectively.

After that, a plug 13 comprising tungsten (W) or the like is formed in each contact hole 12. The plug 13 can be formed, for example, by forming a titanium nitride film 13a that functions as a barrier film on the insulating film 11, which includes the inner portion of the contact hole 12, then forming a tungsten film on the titanium nitride film 13a so as to fill up the contact hole 12 using, for example, the CVD (Chemical Vapor Deposition) method, then removing unnecessary portions of the tungsten film and the titanium nitride film 13a from the insulating film 11 using the CMP (Chemical Mechanical Polishing) method or etching-back method.

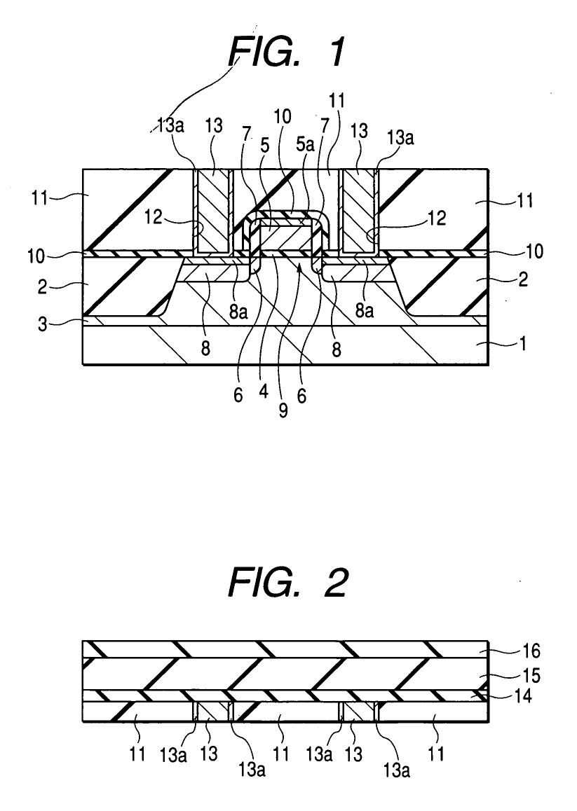

FIGS. 2 through 7 show cross sectional views of major portions of the semiconductor device in manufacturing processes that follow those shown in FIG. 1. In order to simplify the description, the structure of the semiconductor device below the insulating film 11 shown in FIG. 1 is omitted in FIGS. 2 through 7.

As shown in FIG. 2, at first, an insulating film (etching stopper film) 14 is formed on the insulating film 11 in which the plugs 13 are embedded, for example, using the plasma CVD method. The insulating film 14 comes to comprise, for example, a silicon carbidenitride (SiCN) film. A silicon carbide (SiC) film or silicon oxide carbide (SiOC) film may also be used as a deposition material of the insulating film 14. The insulating film 14 is about 25 to 100 nm in thickness. The insulating film 14, when forming grooves and holes for wiring in its upper insulating film (inter-layer insulating film) 15 by etching, is expected to avoid damaging the lower layer and/or degradation of the accuracy of the treatment dimensions due to excessive boring. In other words, the insulating film 14 functions as an etching stopper when etching the insulating film (inter-layer insulating film) 15. After that, an insulating film 15 is formed on the insulating film 14. The insulating film 15 comes to comprise, for example, a fluorine(F)-containing silicon oxide film (silicon oxide film to which fluorine is added), that is, an SiOF film. The insulating film 15 is about 50 to 200 nm in thickness.

After that, an insulating film 16 is formed on the insulating film 15. The insulating film 16 comes to comprise, for example, a silicon oxide film containing no fluorine (F) (silicon oxide film to which no fluorine is added), that is, a silicon oxide (SiOₓ) film represented by silicon dioxide (SiO₂). The insulating film 16 may also be formed of a silicon oxide nitride (SiON) film. The insulating film 16 is about 50 to 200 nm in thickness. Because an SiOF film having a low permittivity (lower than that of the silicon oxide) is used for the insulating film 15, the total permittivity for the wirings of the semiconductor device is lowered, thereby the wiring delay is reduced. The insulating film 16 can prevent diffusion of the fluorine in the insulating film 15. In addition, the insulating film 16 assures the mechanical strength, surface protection, and resistance to humidity of the insulating film 15 respectively, for example, in the CMP treatment process.

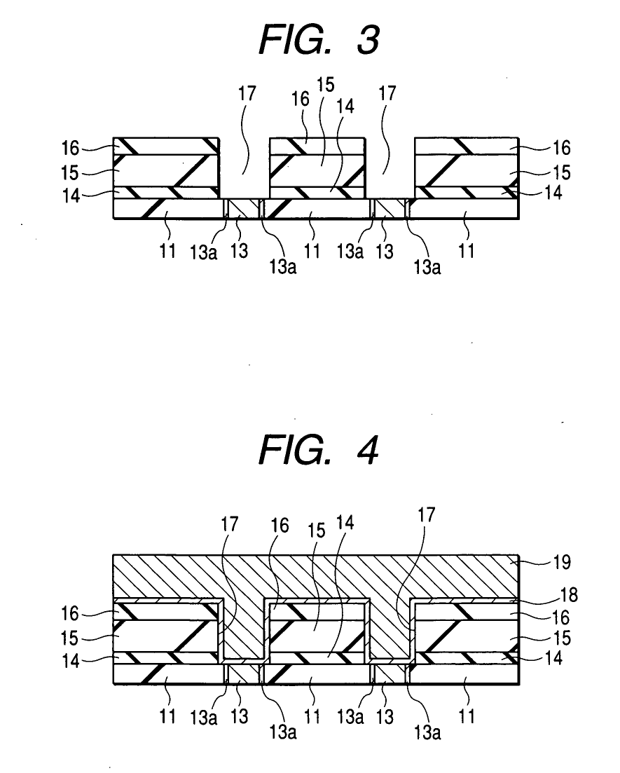

After that, as shown in FIG. 3, the insulating films 14 to 16 are dry-etched by both photo-lithography method and etching method to form apertures (wiring apertures and wiring grooves) 17. At the bottom of each aperture 17 is exposed the top surface of the plug 13.

After that, as shown in FIG. 4, a conductive barrier film 18 having a thickness of about 50 nm is formed of, for example, titanium nitride (TiN) all over the main surface of the semiconductor substrate 1. The spattering method and the CVD method can be used to deposit the conductive barrier film 18. The conductive barrier film 18 suppresses or prevents diffusion of copper used to form the main conductive film (to be described later) and improve the wettability of the copper in the reflowing process of the main conductive film. The conductive barrier film 18 as described above may also be formed of such refractory metal nitride as tungsten nitride (WN) or tantalum nitride (TaN) that hardly reacts to copper instead of titanium nitride. The conductive barrier film 18 may also be formed of a material obtained by adding silicon to refractory metal nitride (Si), as well as such refractory metal as tantalum (Ta) that hardly reacts to copper, titanium (Ti), tungsten (W), titanium tungsten (TiW) alloy. In addition to the above single material films, a laminated film may also be used to form the conductive barrier film 18.

After that, a main conductive film 18 is formed of copper having a thickness of about 800 to 1600 nm on the conductive barrier film 18. The CVD method, the spattering method, or the plating method may be used to form the main conductive film 19. The main conductive film 19 may also be formed of a conductive film comprising mainly, for example, copper or copper alloy (containing Cu as a main component and another component such as Mg, Ag, Pd, Ti, Ta, Al, Nb, Zr, Zn or the like). After that, a seed film is formed of relatively thin copper (or copper alloy) or the like by the spattering method or the like on the conductive barrier film 18, then a main conductive film 19 is formed of relatively thick copper (or copper alloy) or the like on the seed film by the plating method or the like. After that, a thermal treatment is applied to the semiconductor substrate 1 in a non-oxide atmosphere (ex., hydrogen atmosphere) of about 475° C. to reflow the main conductive film 19 and fill up each aperture 17 with copper.

After that, both of the main conductive film 19 and the conductive barrier film 18 are polished by, for example, the CMP method until the surface of the insulating film 16 is exposed. Because unnecessary portions of the films 18 and 19 are removed from the conductive barrier film 16 and both of the conductive barrier film 18 and the main conductive film 19 are left over in each aperture 17, wiring (first layer wiring) 20 comes to comprise the relatively thin conductive barrier film 18 and the relatively thick main conductive film 19 in each aperture 17. The wiring 20 formed such way is connected electrically to the n⁺ type semiconductor regions (source and drain) 8 and the gate electrode 5 through the plugs 13. Unnecessary portions of the films 18 and 19 may also be removed from the insulating film 16 by etching (electrolyte etching or the like).

After that, the semiconductor substrate 1 is disposed in a treatment chamber of the plasma CVD apparatus, then an ammonia gas is introduced into the chamber to apply a plasma power supply to the substrate 1, thereby applying an ammonia (NH₃) plasma treatment on the substrate 1 (particularly on the CMP surface from which the wiring 20 is exposed). Otherwise, a N2 gas and an H2 gas are introduced into the chamber to perform a N2/H2 plasma treatment for the substrate 1. Such a reducing plasma treatment reduces the copper oxide (CuO, Cu₂O, or CuO₂) on the surface of the copper wiring oxidized by CMP to copper (Cu) and forms a copper nitride (CuN) on the surface (very thin region) of the wiring 20.

After that, the substrate 1 is washed as needed, then an insulating film (barrier insulating film) 21 is formed all over the main surface of the semiconductor substrate 1 by the plasma CVD method or the like as shown in FIG. 6. In other words, an insulating film 21 is formed on the insulating film 16 that includes the top surface of the wiring 20. The insulating film 21 is about 25 to 100 nm in thickness. The insulating film 21 functions as a barrier insulating film of the copper wiring. Consequently, the insulating film 21 suppresses or prevents diffusion of the copper contained in the main conductive film 19 of the wiring 20 into an insulating film 22 to be formed later. In addition, the insulating film 21 comes to comprise a material film (having a lower permittivity than the silicon nitride) containing carbon (C) (and silicon (Si), for example, a silicon carbide nitride (SiCN). The insulating film 21 may also be formed of a silicon carbide (SiC) film or silicon oxide carbide (SiOC) film. If the insulating film 21 is formed of any of the above films, the permittivity of the insulating film 21 is reduced more significantly than the silicon nitride film or the like, thereby the inter-wiring capacity is reduced and the operation speed of the semiconductor device is improved.

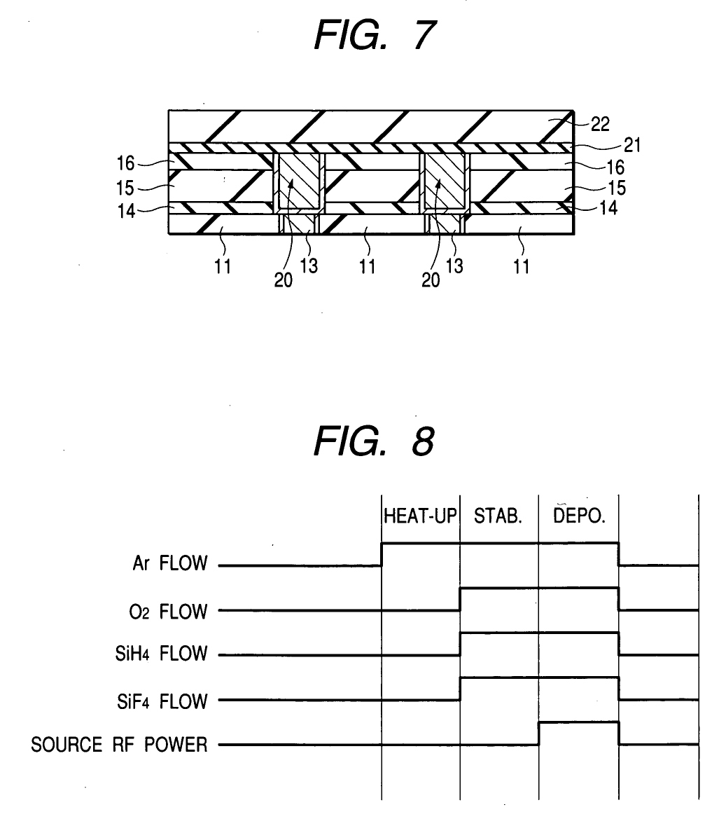

After that, as shown in FIG. 7, an insulating film (inter-layer insulating film) 22 is formed on the insulating film 21. The same material as that of the insulating film 15, that is, a fluorine (F) containing silicon oxide film (SiOF film) is used to form the insulating film 22. The insulating film 22 is about 50 to 200 nm in thickness. The high density plasma chemical vapor deposition (HDP-CVD) method is used to form the insulating film 22. The total wiring permittivity of the semiconductor device is reduced if an SiOF film is used as the insulating film 22. The permittivity of the SiOF film is lower than that of silicon oxide. The wiring delay of the semiconductor device is thus reduced.

If the HDP-CVD apparatus is used to deposit a material film, the semiconductor substrate is heated up to a predetermined deposition temperature by heat-up plasma, then the material film is deposited on the subject semiconductor substrate. In this first embodiment, in the film deposition chamber of the HDP-CVD apparatus in which the semiconductor substrate 1 is disposed, the semiconductor substrate 1 (insulating film 21) is heated up to a predetermined deposition temperature (ex., 420° C.) by plasma (heat-up plasma) generated by a gas that contains no oxygen, for example, an inactive gas (ex., argon (Ar) gas, helium (he) gas, nitrogen (N₂) gas, or mixture of those gases). In this heat-up process for the semiconductor substrate 1 by the heat-up plasma, no oxygen (O₂) is introduced into the chamber. For example, an argon gas (inactive gas) and an oxygen gas are used to generate idle (idling) plasma (argon plasma+oxygen plasma), then the supply of the oxygen gas stops before the semiconductor substrate 1 is disposed in the chamber to form the insulating film 22. Therefore, only the argon plasma (inactive gas plasma) is introduced into the chamber of the HDP-CVD apparatus to heat the semiconductor substrate 1. Consequently, the insulating film 21 of the semiconductor substrate 1 is not exposed to the plasma, so that the surface of the insulating film 21 is prevented or suppressed from oxidization. It takes about 30 seconds to heat the semiconductor substrate 1 up to the predetermined temperature by the heat-up plasma. If both argon gas and oxygen gas are used to generate the idle plasma, the film deposition chamber can be prevented from degradation. When the semiconductor substrate 1 reaches the predetermined deposition temperature, an SiOF film deposition gas (reaction gas) is introduced into the chamber. The SiOF deposition gas is a mixture of a mono-silane (SiH₄) gas, a silicon tetrafluoride (SiF₄) gas, an oxygen (O₂) gas, and an argon (Ar) gas. As a result, the insulating film 22 formed on the insulating film 21 comes to comprise fluoride containing silicon oxide (SiOF). The fluoride density in the insulating film 22 can be adjusted by adjusting the flow of the film deposition gas, for example.

FIG. 8 shows a gas sequence chart of the deposition process of the insulating film 22 (SiOF film here), typically denoting a flow of each gas introduced into the deposition chamber of the HDP-CVD apparatus. As shown in FIG. 8, only the argon (Ar) gas is introduced into the chamber in the heat-up (Heat-up) process. When the semiconductor substrate 1 is heated up to a predetermined film deposition temperature, supply of the mono-silane (SiH₄) gas, the silicon tetrafluoride (SiF₄) gas, and the oxygen (O₂) gas starts. In the stabilization (Stab.) step, no film deposition is done yet. When the gases in the chamber are mixed and homogenized, the deposition (Depo.) step begins by supplying a source RF power in the chamber to deposit the SiOF film on the semiconductor substrate 1.

If a gas containing oxygen, for example, a mixture of an argon gas and an oxygen gas is used as the heat-up plasma for heating the semiconductor substrate 1 up to a predetermined film deposition temperature, the surface of the insulating film 21 is oxidized in the heat-up process of the semiconductor substrate 1. And, the insulating film 21 comprises an SiCN film, an SiC film, an SiOC film or the like, so that it contains carbon as described above. This is why the insulating film 21 is oxidized more easily than the silicon nitride film. If a mixture of an argon gas and an oxygen gas is used as the heat-up plasma, however, the oxidized film becomes about 20 nm in thickness due to the oxidization to occur on the surface of the insulating film 21 as described above. The density of the oxidized film is comparatively low and the film comes to generate cavities therein. When the surface of the insulating film 21 is oxidized by the heat-up plasma, the F (or HF) separated from the SiOF film (insulating film 22) formed thereon comes into the insulating film 21 easily, thereby Si—F and/or C—F bonds are formed at the surface boundary between those insulating films 21 and 22 and such networks as the Si—C and/or Si—N bonds are reduced, resulting in degradation of the adhesive strength (adhesion) that functions between those insulating films 21 and 22. Consequently, the insulating films 21 and 22 might be delaminated from each other. Such a phenomenon occurs when the insulating film 21 is formed of a material containing carbon (and silicon). The phenomenon occurrence is more remarkable when the insulating film 21 is formed of an SiCN film, SiC film, or SiOC film. The phenomenon occurrence is still more remarkable when the insulating film 21 is formed of an SiCN film or SiC film containing no oxygen.

In this first embodiment, only an inactive gas (ex., argon gas) containing no oxygen (O₂ gas) is used to generate heat-up plasma used to heat the semiconductor substrate 1 up to a predetermined film deposition temperature (ex., about 420° C.). When the semiconductor substrate 1 reaches the predetermined temperature, deposition gases such as a mono-silane (SiH₄) gas, a silicon tetrafluoride (SiF₄) gas, an oxygen (O₂) gas, and an argon (Ar) gas are introduced into the deposition chamber, then the heat-up plasma is generated by a source RF power or the like and used to form the insulating film 22 comprising an SiOF film. The oxygen (O₂) gas is introduced into the chamber in the deposition process of the SiOF film (insulating film 22) after the semiconductor substrate 1 reaches the predetermined deposition temperature. The insulating film 21 is thus suppressed/prevented from oxidization. Consequently, the surface of the insulating film 21 is hardly oxidized, so that forming of an oxidized film on the surface of the insulating film 21 is suppressed or prevented. For example, the thickness of the oxidized film to be formed on the surface of the insulating film 21 is suppressed to 10 nm and under (reduced to about a half and under than when both oxygen gas and argon gas are used to generate the heat-up plasma). Consequently, the invasion of the fluorine (F) (or the hydrogen fluoride (HF)) separated from the insulating film 22 (into the insulating film 21 or the surface oxide film) is suppressed or prevented. It is thus prevented that Si—F/C—F bonds are formed at the surface boundary between the insulating films 21 and 22, thereby such networks as the Si—C and i-N bonds do not decrease. This is why the adhesion (adhesive strength) that functions between the insulating films 21 and 22 is improved and the insulating films 21 and 22 are suppressed or prevented from delamination from each other. In addition, because the surface of the insulating film 21 is suppressed from oxidization, the insulating film 21 prevents degradation of its function as a barrier insulating film for preventing diffusion of copper in the main conductive film of the wiring 20.

In this first embodiment, heat-up plasma generated by a no-oxygen containing gas should be used to deposit the fluorine containing silicon oxide film (insulating film 22) The no-oxygen containing gas may be any of such inactive gases as an argon (Ar) gas, a helium (He) gas, a nitrogen (N₂) gas, and a mixture of those gases. The nitrogen (N₂) gas that might nitride the lower insulating film 21 can be used for forming the insulating film 21 comprising such a film as an SiCN film containing nitrogen. The argon (Ar) gas can be used to shorten the heat-up time of the semiconductor substrate 1.

Although no description has been made for the deposition process of the insulating film 15, the insulating film 15 can be formed on the insulating film 14 using the HDP-CVD method just like the insulating film 21, for example, by forming the insulating film 14, then heating the semiconductor substrate 1 (insulating film 14) up to a predetermined deposition temperature with the heat-up plasma generated by a gas containing no oxygen. The insulating film 15 comes to comprise an SiOF film. Consequently, the surface of the insulating film 14 is suppressed or prevented from oxidization, thereby the adhesion (adhesive strength) that functions between the insulating films 14 and 15 is improved. Consequently, the insulating films 14 and 15 is suppressed or prevented from delamination.

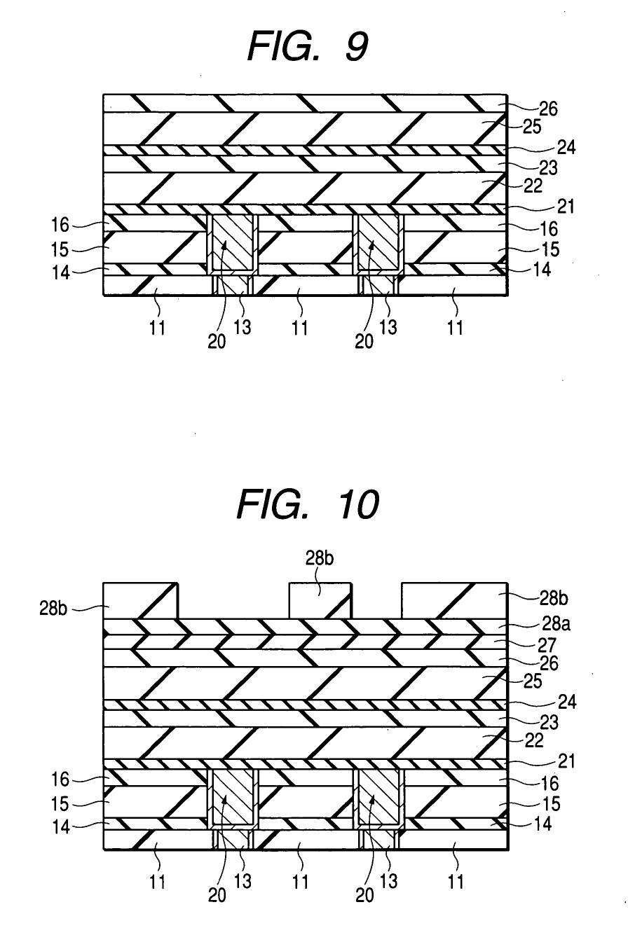

FIGS. 9 through 19 show cross sectional views of major portions of the semiconductor device in the manufacturing processes that follow those shown in FIG. 7. In order to simplify the description, the portion corresponding to the structure of the semiconductor device below the insulating film 11 in FIG. 1 is not shown here.

After forming the insulating film 22 as described above, as shown in FIG. 9, an insulating film 23 is formed on the insulating film 22. The insulating film 23 comes to comprise the same material that is a silicon oxide film containing no fluorine (F) here, that is, a silicon oxide (SiOₓ) film represented by silicon dioxide (SiO₂). The insulating film 23 may also be formed of a silicon oxide nitride (SiON) film. The insulating film 23 is about 50 to 200 nm in thickness. The insulating film 23 prevents diffusion of the fluorine in the insulating film 22.

After that, an insulating film (etching stopper film) 24 is formed on the insulating film 23. The insulating film 24 comes to comprise the same material as that of the insulating film 21, for example, a silicon carbide nitride (SiCN) film. The insulating film 24 may also be formed of a silicon carbide (SiC) or silicon oxide carbide (SiOC) film. The insulating film 24 is about 10 to 50 nm in thickness. Then, an insulating film (inter-layer insulating film) 25 is formed on the insulating film 24, then an insulating film 26 is formed on the insulating film 25. The insulating film 25 comes to comprise the same material as that of the insulating film 22, for example, a silicon oxide (SiOF) film containing fluorine (F). The insulating film 25 is about 50 to 200 nm in thickness. The insulating film 26 comes to comprise the same material as that of the insulating film 23, for example, a silicon oxide (SiO₂) film or silicon oxide nitride (SiON). The insulating film 26 can prevents diffusion of fluorine in the insulating film 25. The insulating film 26 is about 50 to 200 nm in thickness. The insulating films 24 and 25 can be formed in the same process as that of the insulating films 21 and 22. Consequently, in the process for forming the insulating film 25 to comprise an SiOF film, a gas containing no oxygen (inactive gas, for example, argon gas) is used to generate the heat-up plasma just like in the process for forming the insulating film 22. Then, the semiconductor substrate 1 is heated up to a predetermined deposition temperature, then predetermined deposition gases (the SiH₄ gas, the SiF₄ gas, the O₂ gas, and the Ar gas) are introduced into the deposition chamber to deposit the SiOF film (insulating film 25). Consequently, the adhesion (adhesive strength) that functions between the insulating films 24 and 25 is improved, thereby the insulating films 24 and 25 are suppressed or prevented from delamination.

After that, as shown in FIG. 10, an insulating film (hard masking layer) 27 is formed on the insulating film 26. Then, a reflection preventive film 28a is formed on the insulating film 27 and a photo-resist film is formed on the reflection preventive film 28a. The photo-resist film is patterned by exposure or the like to form a photo-resist pattern 28b. The photo-resist pattern 28b has apertures formed in its flat region on which wiring is to be formed.

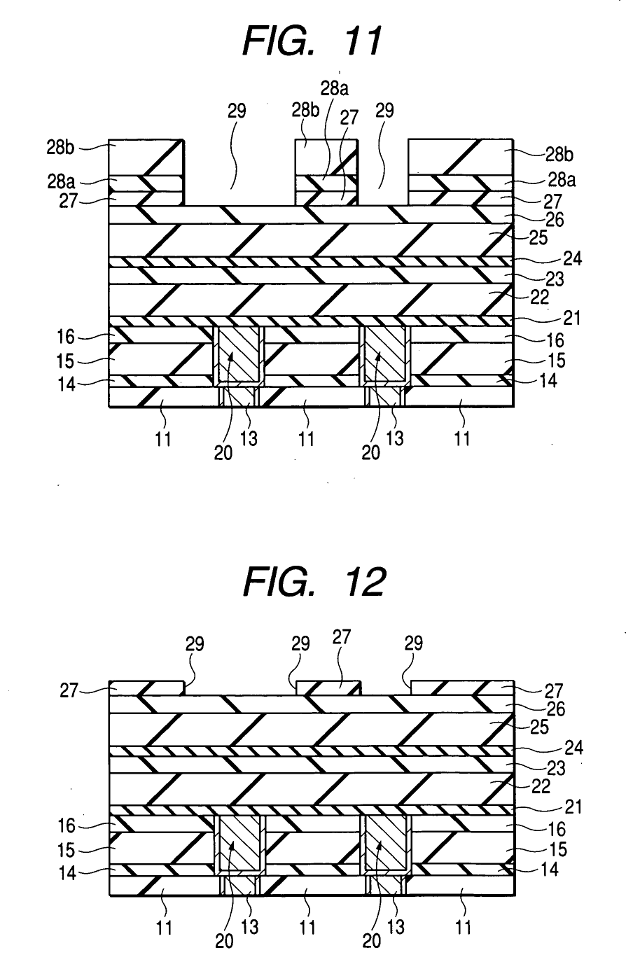

After that, as shown in FIG. 11, the reflection preventive film 28a is removed selectively by the dry-etching method. The photo-resist pattern 28b is used as an etching mask for this removal. Then, the insulating film 27 is removed selectively by the dry-etching method using the photo-resist pattern 28b as an etching mask to form apertures 29. The apertures 29 are formed in the flat region (position) corresponding to a region reserved for forming wiring.

After that, as shown in FIG. 12, the residual photo-resist pattern 28b and the residual reflection preventive film 28a are removed by ashing or the like respectively.

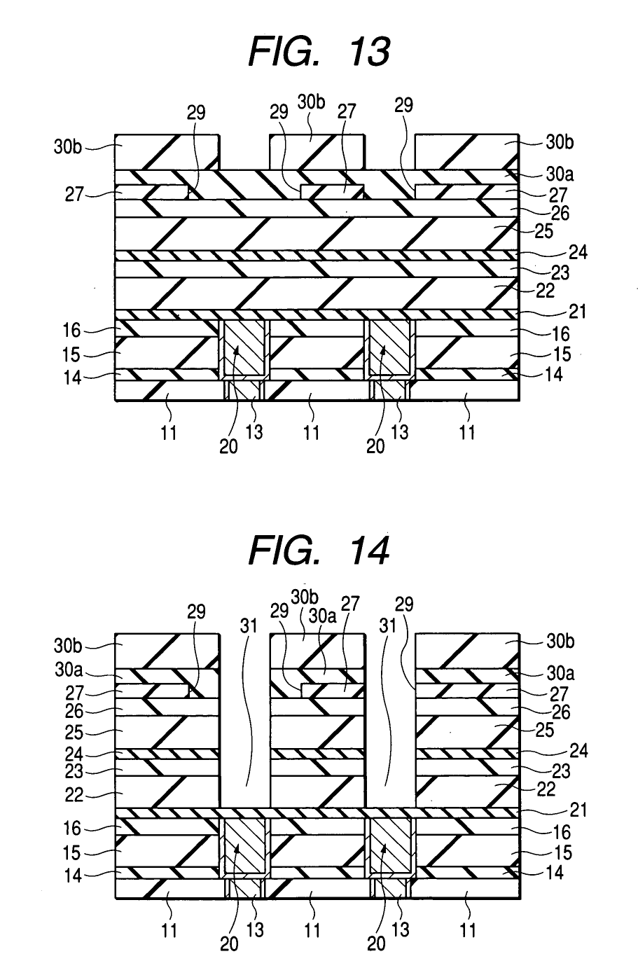

After that, as shown in FIG. 13, a reflection preventive film 30a is formed on the insulating film 27 so as to fill up the apertures 29. Then, a photo-resist film is formed on the reflection preventive film 30a and the photo-resist film is patterned by exposure or the like to form a photo-resist pattern 30b. The photo-resist pattern 30b has apertures in its flat region on which via holes are to be formed.

After that, as shown in FIG. 14, the reflection preventive film 30a is removed selectively by the dry-etching method using the photo-resist pattern 30b as an etching mask. Then, the insulating films 26, 25, 24, 23, and 22 are removed selectively by the dry-etching method using the photo-resist pattern 30b as an etching mask to form apertures 31. The insulating film 21 functions as an etching stopper film at this time. The apertures 31 are formed in a flat region corresponding to an area reserved for forming via holes. The flat region of the apertures 31 is included in the flat region of the apertures 29.

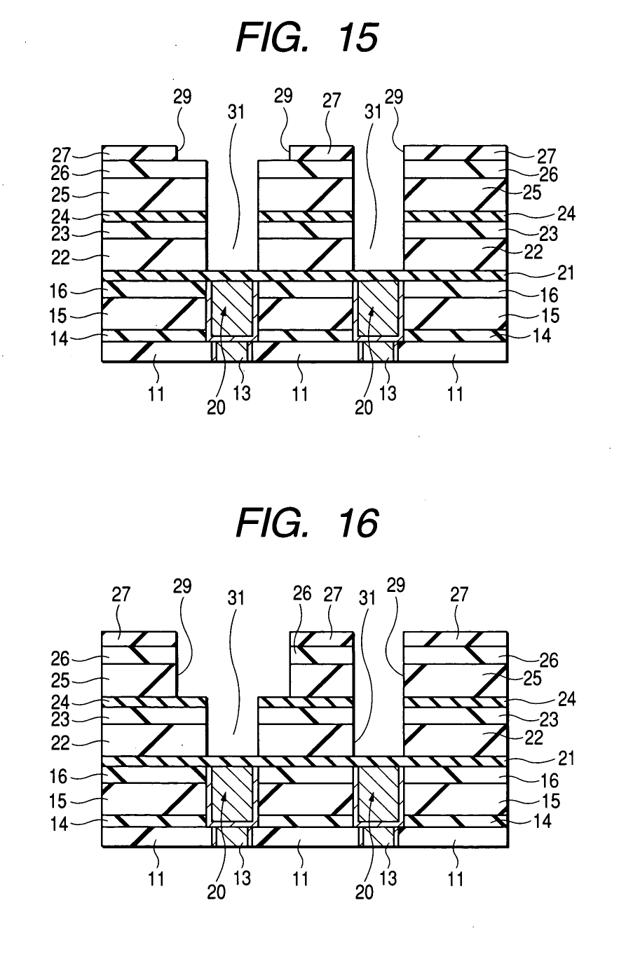

After that, as shown in FIG. 15, the residual photo-resist pattern 30b and the residual reflection preventive film 30a are removed by ashing or the like respectively. Then, as shown in FIG. 16, the insulating films 26 and 25 exposed at the bottom of each aperture 29 are removed selectively by dry-etching using the insulating film 27 as an etching mask. The insulating film 24 functions as an etching stopper film at this time.

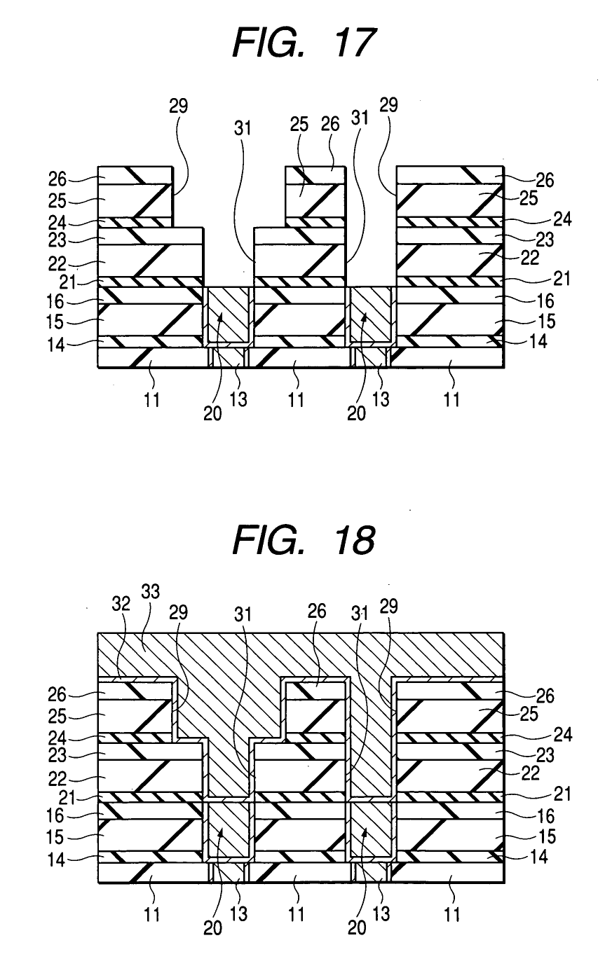

After that, as shown in FIG. 17, the insulating film 24 exposed at the bottom of each aperture 29 and the insulating film 21 exposed at the bottom of each aperture 31 are removed selectively by dry-etching. Consequently, the top surface of the wiring 20 is exposed at the bottom of each aperture 31. Although the insulating film 27 is removed in this dry-etching process, the insulating film 27 may also be removed in another dry-etching process to be performed later. The insulating film 26 is thus exposed.

After that, as shown in FIG. 18, a conductive barrier film 32 is formed by the spattering method all over the main surface of the semiconductor substrate 1 (that is, on the insulating film 26 including the bottoms and side walls of the apertures 29 and 31) with the same material as that of the conductive barrier film 18, for example, titanium nitride. Then, a main conductive film 33 is formed of copper on the conductive barrier film 32 just like the main conductive film 19 so as to fill up the apertures 29 and 31. The main conductive film 33 can be formed by the CVD method, spattering method, plating method, or the like. The main conductive film 33 may be formed of a conductive film comprising mainly copper, for example, copper or copper alloy (with Cu as the main component and includes, for example, Mg, Ag, Pd, Ti, Ta, Al, Nb, Zr, Zn, or the like) Then, a seed film is formed on the conductive barrier film 32 by the spattering method or the like. After that, the main conductive film 33 may also be formed on the seed film using a plating method or the like. After that, a thermal treatment is applied to the semiconductor substrate 1 in a non-oxide atmosphere (ex., hydrogen atmosphere) at about 475° C., thereby reflowing the main conductive film 33 to fill up the apertures 29 and 31 with copper.

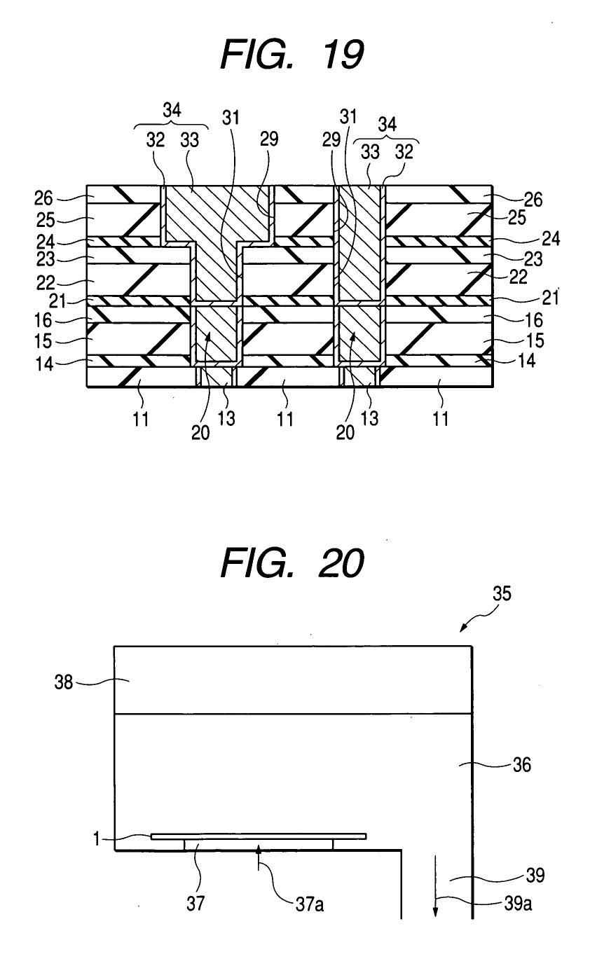

After that, as shown in FIG. 19, the main conductive film 33 and the conductive barrier film 32 are polished by, for example, the CMP method until the top surface of the insulating film 26 is exposed. This CMP method may also be used to remove the insulating film 27 in the same process. When unnecessary portions of the films 32 and 33 are removed from the insulating film 26 while those films 32 and 33 are left over in the wiring aperture part consisting of the apertures 29 and 31, wiring (the second layer wiring) 34 is formed in the wiring aperture part comprising the apertures 29 and 31. The wiring 34 that includes both of a relatively thin conductive barrier film 32 and a relatively thick conductive film 33 is connected electrically to the wiring 20. The apertures 29 correspond to wiring grooves and the apertures 31 correspond to holes or via holes used for the connection between the upper wiring (wiring 34) and the lower wiring (wiring 20). Consequently, the conductors (conductive barrier film 32 and main conductive film 33) embedded in the apertures 29 come to correspond to the wirings and the conductors (conductive barrier film 32 and main conductive film 33) embedded in the apertures 31 come to correspond to the via holes or plugs.

After that, the second layer wiring (wiring 34) process is repeated as needed to form the upper wirings above the third layer wiring. However, the description for the process will be omitted here.

In this embodiment, when forming the insulating films 22 and 25 comprising a silicon oxide film (SiOF) containing fluorine (F) on the insulating films 21 and 24 comprising a material film containing carbon (and silicon) as described above, the semiconductor substrate 1 is heated up to a predetermined deposition temperature by plasma (heat-up plasma) generated by a gas containing no oxygen (ex., an inactive gas of argon, helium, nitrogen, or the like). After that, the deposition gas of the insulating films 22 and 25 is introduced into the deposition chamber to form the insulating films 22 and 25. Consequently, the surface of the insulating films 21 and 24 is suppressed from oxidization; thereby, the adhesion (adhesive strength) that functions between the insulating films 21 and 22, as well as between the insulating films 24 and 25 is improved. And, the insulating films 21 and 22, as well as the insulating films 24 and 25 are thus prevented from delamination respectively. In addition, the reliability and the manufacturing yield of the semiconductor devices are improved.

Furthermore, because it is possible to use a silicon carbide (SiC) film, a silicon carbide nitride (SiCN) film, or a silicon oxide carbide (SiOC) film having a lower permittivity than the silicon nitride film as a barrier insulating film and an etching stopper insulating film for copper wiring, the inter-wiring capacity of the semiconductor device is reduced, thereby the operation speed of the semiconductor device is improved. In addition, because a silicon oxide (SiOF) film containing fluorine can be used as an inter-layer insulating film (as the inter-wiring insulating film 25 and the inter-via insulating film 22), the inter-wiring capacity of the semiconductor device is reduced, thereby the operation speed of the semiconductor device is improved.

Furthermore, in this first embodiment, the wiring aperture part (comprising apertures 29 and 31) is formed in the process shown in FIGS. 9 through 17. However, the wiring aperture part may also be formed in another process (method) For example, it is possible to form the apertures 31 in the insulating film 24 by the photo-lithography method, then form the insulating films 25 to 27 (the apertures 31 are formed in the insulating film 24 in the process shown in FIG. 9 in this case), then form the apertures 29 in the insulating film 27 by the photo-lithography method, then dry-etch the insulating films 26 and 25 to be exposed from the apertures 29 of the insulating film 27 and dry-etch the insulating films 23 and 22 to be exposed from the apertures 31 of the insulating film 24 to obtain the structure shown in FIG. 16. After that, the insulating film 21 at the bottom of each aperture 31, as well as the insulating film 24 at the bottom of each aperture 29 are removed by dry-etching.

Furthermore, in this first embodiment, the semiconductor substrate 1 is heated up to a predetermined deposition temperature by plasma (heat-up plasma) generated by a gas containing no oxygen (ex., an inactive gas of argon) in the deposition process of the SiOF films (insulating films 15, 21, and 25) by the HDP-CVD method, then the SiOF film deposition gases are introduced into the deposition chamber of the HDP-CVD apparatus to form the SiOF films. However, it is also possible to use a heating mechanism provided newly in the HDP-CVD apparatus to heat the semiconductor substrate 1 disposed in the deposition chamber up to the predetermined deposition temperature, then introduce SiOF film deposition gases into the chamber to form the SiOF films (insulating films 15, 22, and 25).

For example, as shown in FIG. 20, the heating mechanism (ex., a heater, a lamp heating device, or the like) is provided in the wafer stage 37 in the film deposition chamber 36 of the HDP-CVD apparatus beforehand, then the semiconductor substrate 1 disposed on the wafer stage 27 is heated by the heating mechanism. When the semiconductor substrate 1 reaches the predetermined deposition temperature, the SiOF film deposition gas is introduced into the chamber through a gas supply mechanism (not shown) so that a biased RF voltage source or RF power is applied to the semiconductor substrate 1 to generate plasma from a high density plasma source (ICP, helicon or ECR) 38 to deposit the SiOF film on the semiconductor substrate 1. The deposition chamber 36 can be pumped 39a from a pumping port 39.

Because there is no need to heat the semiconductor substrate 1 by the heat-up plasma if the SiOF film is formed such way, the surface of the insulating film (the insulating films 14, 21, and 24) located below each SiOF film is suppressed or prevented from oxidization. Consequently, the SiOF film is suppressed or prevented from delamination.

Second Embodiment

In the first embodiment described above, oxidization to occur on the surface of each of the lower layers (the insulating films 21 and 24) is suppressed or prevented, since the heat-up plasma is generated by a gas containing no oxygen and used to form the SiOF films (the insulating films 22 and 25). The SiOF films (the insulating films 22 and 25) are thus prevented from delamination.

In this second embodiment, however, in order to prevent the SiOF films from delamination, the heat-up plasma is generated from an inactive gas, then a plasma treatment is applied to each layer formed just under its adjacent SiOF film to be formed later.

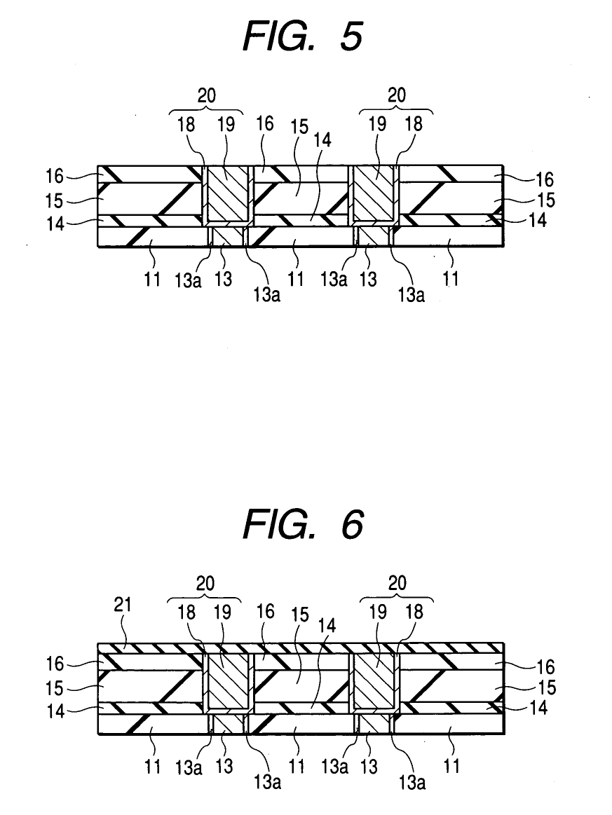

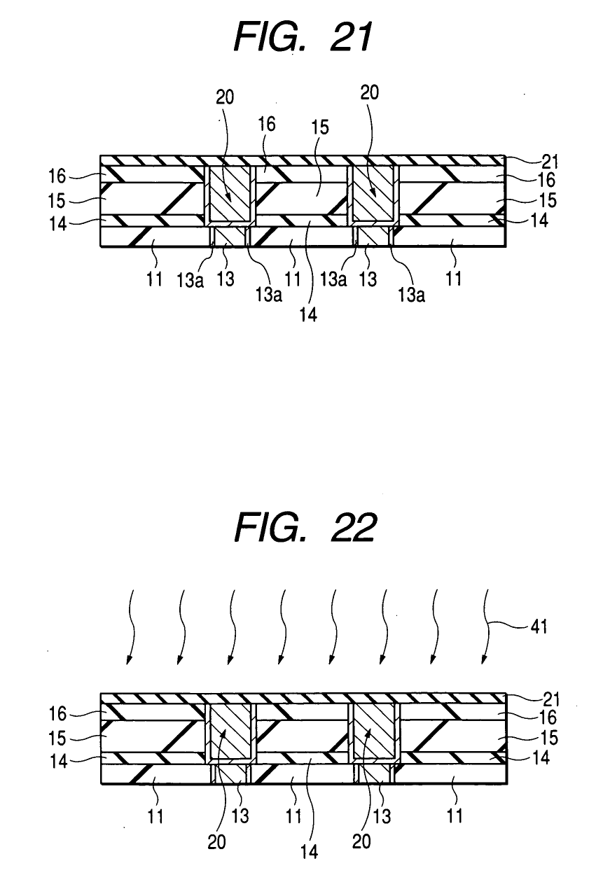

FIGS. 21 and 22 show cross sectional views of major portions of a semiconductor device in manufacturing processes in the second embodiment of the present invention. In order to simplify the description, the structure of the semiconductor device below the insulating film 11 shown in FIG. 1 is omitted here. The manufacturing processes shown in Figs up to FIG. 5 are the same as those in the first embodiment, so that the description for them will be omitted here; only the manufacturing processes that follow those shown in FIG. 5 will thus be described below.

After obtaining the structure of the semiconductor device shown in FIG. 5, an insulating film (barrier insulating film) 21 is formed by the plasma CVD method or the like all over the semiconductor substrate 1 (that is, on the insulating film 16 including the top surface of the wiring 20). The insulating film 21 suppresses or prevents diffusion of the copper contained in the main conductive film of the wiring 20 into an insulating film 22a to be formed later. The insulating film 21 comes to comprise a material film (insulating film having a lower permittivity than silicon nitride) containing carbon (C) (and silicon (Si)) just like in the first embodiment. For example, the insulating film 21 comprises a silicon carbide nitride (SiCN) film. The insulating film 21 may also be formed of another material, for example, a silicon carbide (SiC) film or silicon oxide carbide (SiOC) film. If the insulating film 21 is formed of any of the above material films, the permittivity can be reduced more significantly than the silicon nitride film. The inter-wiring capacity of the semiconductor device is thus reduced, thereby the operation speed of the semiconductor device is improved.

If the semiconductor substrate 1 is left in the atmosphere after the insulating film 21 is formed, the CH₃ group on the surface of the insulating film 21 might absorb the moisture content. In such a case, if oxidization occur on the surface of the insulating film 21 in the deposition process of the insulating film 22a, a moisture content containing oxide film comes to be formed on the surface of the insulating film 21. And, this accelerates diffusion of fluorine or hydrogen fluoride into the insulating film 21 from an insulating film (SiOF film) 22a to be formed later. As a result, the adhesion (adhesive strength) that functions between the insulating films 21 and 22a is degraded; thereby the insulating films 21 and 22a come to be delaminated easily.

In this second embodiment, therefore, in order to prevent the surface of the insulating film 21 from such absorption of the moisture content, a plasma treatment is applied to the semiconductor substrate 1 (surface of the insulating film 21) using an inactive gas after forming the insulating film 21. The inactive gas may be, for example, a helium (He) gas. As shown in FIG. 22 typically, the surface of the insulating film 21 is exposed to the helium plasma 41. Consequently, the CH₃ (CH₃ group, —CH₃ bonds), etc. are removed from the surface of the insulating film 21. And, the Si—C and Si—N bonds increase on the surface of the insulating film 21, thereby the surface of the insulating film 21 is suppressed or prevented from absorption of the moisture content.

This is why even when the surface of the insulating film 21 comes to be oxidized (an oxide film is formed) in the deposition process of the insulating film 22a to be performed later, the oxide film is suppressed or prevented from generation of cavities therein due to an increase of Si—C and i-N bonds. In addition, the oxide film formed on the surface of the insulating film 21 is prevented from invasion of the moisture content. And, because there is no moisture content on the surface of the insulating film 21 nor in the oxide film even when the fluorine (F) is separated from the SiOF film after the SiOF film (insulating film 22a) is formed, it is possible to suppress generation of the hydrogen fluoride (HF), as well as to suppress or prevent diffusion of F or HF in the insulating film 21. Consequently, it is possible to prevent i-F and C—F bonds from being formed at the surface boundary between the insulating films 21 and 22a. Thus, such networks as Si—C and i-N do not decrease, thereby the adhesion (adhesive strength) that functions between the insulating films 21 and 22a is improved and the insulating films 21 and 22a are suppressed or prevented from delamination.

In addition to the helium plasma treatment, the nitrogen plasma treatment (plasma treatment with a nitrogen gas) is also effective in this case. However, the nitrogen plasma treatment must be limited so as not to nitride the insulating film 21. On the other hand, the helium plasma treatment is controlled easily and can reduce damages that might occur at the semiconductor substrate 1, so that it is recommended more favorably. In these second and other embodiments, the nitrogen gas is included in the inactive gasses.

It is also possible to deposit the insulating film 21 by the plasma CVD method (plasma CVD apparatus), then introduce only an inactive gas (ex., the helium gas) in the same chamber to generate plasma and perform a plasma treatment (ex., helium plasma treatment) on the surface of the insulating film using the inactive gas. In that case, the helium plasma treatment requires no additional process after the insulating film 21 deposition process, thereby the manufacturing process of the semiconductor device is simplified.

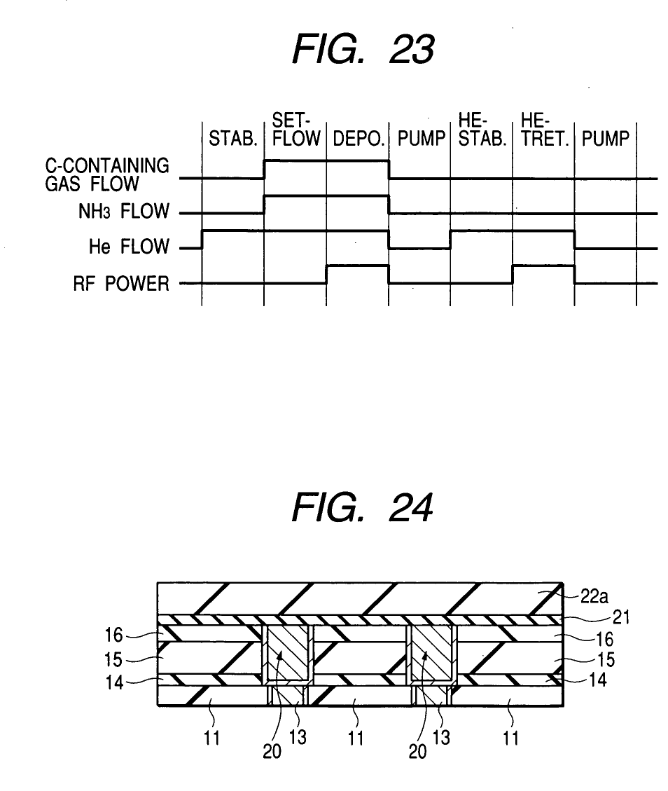

FIG. 23 shows a gas sequence chart of the SiCN film deposition process, as well as the flow of each gas introduced into the plasma CVD apparatus typically. As shown in FIG. 23, at first, a helium gas is introduced into the deposition chamber (in the stabilization (Stab.) step), then a carbon (C) containing gas and an ammonia (NH₃) gas are introduced into the chamber as film deposition gases (in the set-flow step), then a source RF power is supplied in the chamber to deposit an SiCN film on the surface of the insulating film (in the deposition (Depo.) step). After that, supply of the source RF power and the gases stops and the gases are pumped from the deposition chamber (pumping (Pump) step). After that, a helium gas is introduced into the deposition chamber. When the gas flow is stabilized ((He-stab.) step), a source RF power is supplied into the chamber to perform a helium plasma treatment on the surface of the SiCN film (helium plasma treatment (He-tret.) step). After this helium plasma treatment ends, supply of both source RF power and helium gas stops and the gases are pumped from the deposition chamber (pumping (Pump) step). The deposition of the SiCN film and the helium plasma treatment on the surface of the SiCN film can thus be made continuously.

FIGS. 24 through 27 show cross sectional views of major portions of the semiconductor device in the manufacturing processes that follow those shown in FIG. 22. In order to simplify the description, the structure of the semiconductor device below the insulating film 11 shown in FIG. 1 is omitted here in FIGS. 24 through 27.

After a helium plasma treatment, as shown in FIG. 24, an insulating film (inter-layer insulating film) 22a is formed on the insulating film 21. The insulating film 22a comprises a fluorine (F) containing silicon oxide film (SiOF film) just like the insulating film 21 in the first embodiment. Because an SiOF film of which permittivity is low (low permittivity film) is used as the insulating film 22a such way, the total permittivity of the wirings of the semiconductor device is reduced, thereby the wiring delay of the semiconductor device is reduced.

The insulating film 22a (SiOF film) can be deposited as follows just like in the first embodiment. At first, heat-up plasma is generated by a gas containing no oxygen (ex., an inactive gas of argon) and the semiconductor substrate 1 is heated up to a predetermined deposition temperature, then predetermined film deposition gases (an SiH₄ gas, an SiF₄ gas, an O₂ gas, and an Ar gas) are introduced into the deposition apparatus (ex., HDP-CVD apparatus). Consequently, the surface of the insulating film 21 is suppressed or prevented from oxidization, thereby the adhesion (adhesive strength) that functions between the insulating films 21 and 22a is improved. In addition, because oxidization to occur on the surface of the insulating film 21 is suppressed as described above, the insulating film 21 that functions as a barrier insulating film is prevented from degradation of the function so that the insulating film 21 can prevent diffusion of the copper contained in the wiring 20 into the main conductive film 19.

In another aspect of the second embodiment, an oxygen containing gas (ex., a mixture of an argon gas and oxygen) can generate the heat-up plasma used in the deposition process of the insulating film 22a. In that connection, the oxide film comes to be formed thicker on the surface of the insulating film 21 due to the oxidization by the heat-up plasma. However, because a helium plasma treatment is applied to the insulating film 21 before the insulating film 22a is deposited, almost no moisture content goes into the oxide film even when the surface of the insulating film 21 is oxidized. Consequently, diffusion of the F or HF into the insulating film 21 from the insulating film (SiOF film) 22a is suppressed or prevented, thereby the adhesion (adhesive strength) that functions between the insulating films 21 and 22a is improved. And, the insulating films 21 and 22a are suppressed or prevented from delamination.

Furthermore, the insulating film 22a may also be formed of HSQ (hydrogen selsesquioxane), MSQ (methyl silsesquioxane), or organic polymer (including their porous materials). Low permittivity materials of the organic polymer group usable as the insulating film 22a are, for example, SiLK (made by the Dow Chemical Co., specific permittivity=2.7, heat resistant temperature=490° C. and over, insulation breakdown withstand voltage=4.0 to 5.0 MV/Vm). In that case, the insulating film 22a can be formed by a coating method or the like. Even when the insulating film 22a is formed of such a material (HSQ, MSQ, or organic polymer), absorption of the moisture content on the surface of the insulating film 21 should be avoided while the insulating film 22a is formed. Otherwise, the adhesion that functions between the insulating films 21 and 22a is degraded, thereby the insulating films 22a might be delaminated from the insulating film 21. In this second embodiment, to avoid such a trouble, a plasma treatment (ex. helium plasma treatment) is applied to the surface of the insulating film 21 by the heat-up plasma generated by an inactive gas to prevent the surface of the insulating film 21 from absorption of the moisture content before forming the insulating film 22a. The adhesion (adhesive strength) that functions between the insulating film 21 and the insulating film 22a comprising HSQ, MSQ, or organic polymer is thus improved, thereby those insulating films 21 and 22a are prevented from delamination.

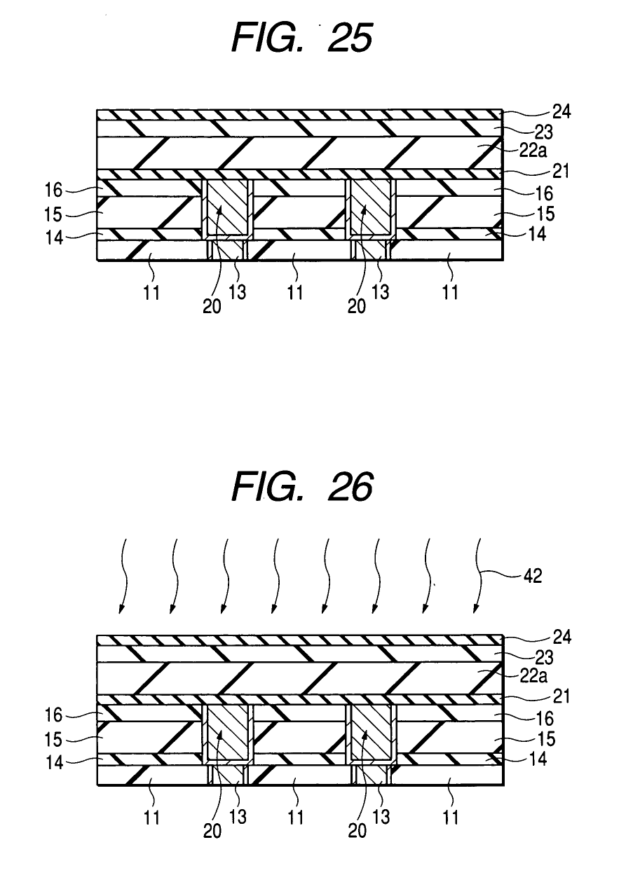

After that, just like in the first embodiment, an insulating film 23 and an insulating film (etching stopper film) 24 are formed on the insulating film 22a as shown in FIG. 25. The insulating film 23 comes to comprise, for example, a silicon oxide (SiOₓ) film or silicon oxide nitride (SiON) film and prevents diffusion of fluorine in the insulating film 22. The insulating film 24 comes to comprise, for example, a silicon carbide nitride (SiCN) film, a silicon carbide (SiC) film, or silicon oxide carbide (SiOC) film and functions as an etching stopper film in the dual damascene process.

Furthermore, even when the insulating film 22a comprises HSQ, MSQ, or organic polymer, the insulating film 23 comprises, for example, a silicon oxide (SiOₓ) film or silicon oxide nitride (SiON) film and can protect the insulating film 22a. If the insulating film 22a comprises a material that might be damaged by the oxygen plasma (ex., the SiLK or the like), it is also possible to form a silicon nitride film, silicon carbide, or silicon carbide nitride film on the insulating film 22a, then form an insulating film 23 thereon. Consequently, the oxidization resistance of the insulating film 22a is improved (the insulating film 22a is prevented from oxidization).

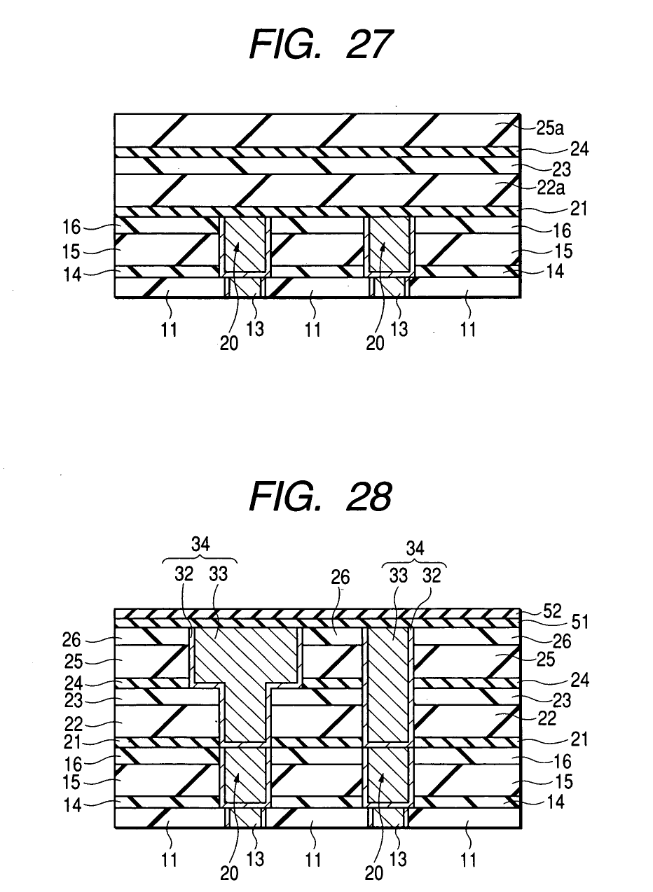

In this second embodiment, after the insulating film 24 is formed, a plasma treatment (ex., helium (He) plasma treatment) is applied to the semiconductor substrate 1 (the surface of the insulating film 24) with the heat-up plasma generated by an inactive gas just like the insulating film 21. For example, as shown in FIG. 26 typically, the surface of the insulating film 21 is exposed to the helium plasma 42. Consequently, the surface of the insulating film 24 is suppressed or prevented from absorption of the moisture content just like the insulating film 21. After that, as shown in FIG. 27, an insulating film (inter-layer insulating film) 25a is formed of a fluorine (F) containing silicon oxide film (SiOF film) just like the insulating film 22a.

Because a plasma treatment (ex., helium plasma treatment) is applied to the semiconductor substrate 1 with the heat-up plasma generated by an inactive gas after forming the insulating film 24, then the insulating film 25a is formed, the surface of the insulating film 24 is suppressed or prevented from absorption of the moisture content. Consequently, even when oxidization occurs (an oxide film is formed) on the surface of the insulating film 21 in the insulating film 24 deposition process, diffusion of the F or HF from the insulating film (SiOF film) 25a is suppressed or prevented. The adhesion (adhesive strength) that functions between the insulating films 24 and 25a is thus improved, thereby the insulating films 24 and 25a is suppressed or prevented from delamination. In addition, in this second embodiment, HSQ, MSQ, or organic polymer (including their porous materials) can be used to form the insulating film 25a. Also in that case, the insulating films 24 and 25a is suppressed or prevented from delamination just like the insulating film 21.

After that, an insulating film 26 is formed on the insulating film 25a, then wiring 23 is formed thereon just like in the first embodiment. However, because the process for forming the insulating film 26 and its subsequent processes are the same as those in the first embodiment, the description for them will be omitted here.

In this second embodiment, a plasma treatment is applied to the surface of each of the insulating films 21 and 24 by the heat-up plasma generated by an inactive gas after forming the insulating films 21 and 24 under each SiOF film (or an HSQ, MSQ, or organic polymer film), then the insulating films (SiOF film, HSQ, MSQ, or organic polymer film) 22a and 25a are formed. Consequently, the surface of each of the insulating films 21 and 24 is prevented from absorption of the moisture content, thereby the insulating films (SiOF film, HSQ, MSQ, or organic polymer film) 22a and 25a are prevented from delamination. Both reliability and manufacturing yield of the semiconductor devices is thus improved.

Third Embodiment

FIGS. 28 through 33 show cross sectional views of a semiconductor device in manufacturing processes in the third embodiment of the present invention. In order to simplify the description, the structure of the semiconductor device below the insulating film 11 shown in FIG. 1 is omitted here. And, the manufacturing processes shown in up to FIG. 19 are the same as those in the first embodiment. The description for them will thus be omitted here and only the manufacturing processes that follow those shown in FIG. 19 will be described below.

After obtaining the structure of the semiconductor device shown in FIG. 19, such a reducing plasma treatment as an ammonia (NH₃) plasma treatment is applied to the semiconductor substrate 1 just like that applied after the wiring 20 is formed. Consequently, the copper oxide (CuO, Cu₂O, or CuO₂) on the surface of the copper wiring (wiring 34) oxidized by CMP is reduced to copper (Cu), then a copper nitride (CuN) layer is formed on the surface (a very thin region) of the wiring 20.

After that, the surface of the substrate 1 is washed as needed, then an insulating film (barrier insulating film) 51 is formed all over the main surface of the semiconductor substrate 1 by the plasma CVD method as shown in FIG. 28. In other words, the insulating film 51 is formed on the insulating film 26 that includes the top surface of the wiring 34. The insulating film 51 suppresses or prevents diffusion of the copper contained in the main conductive film of the wiring 34 into an insulating film 52 to be formed later. The insulating film 51 comprises the same material as that of the insulating film 21, for example, a silicon carbide nitride (SiCN) film. The insulating film 51 may also comprise another material, for example, a silicon carbide (SiC) film or silicon oxide carbide (SiOC) film. If the insulating film 51 comprises any of the above films, the permittivity is reduced more significantly than the silicon nitride film, etc. It is thus possible to reduce the inter-wiring capacity and improve the operation speed of the semiconductor device. The insulating film 51 is about 25 to 100 nm in thickness.

After that, an insulating film 52 is formed on the insulating film 51. The insulating film 52 is formed of, for example, a silicon oxide (SiOₓ) film. The insulating film 52 may also be formed of another material, for example, a silicon oxide nitride (SiON) film. Such a plasma CVD method as the parallel planar type plasma CVD method (apparatus) or the like is used to form the insulating film 52. The plasma density in the deposition process of the insulating film 52 should be lower than that in the deposition process of an insulating film (SiOF film) 53 to be described later. Otherwise, it should be 1×10¹¹/cm³ and under (for example, about 1×10¹⁰/cm³ to 1×10¹¹/cm³). Consequently, the plasma density becomes low favorably in the deposition process of the insulating film 52, so that the surface of the insulating film 51 is suppressed or prevented from oxidization.

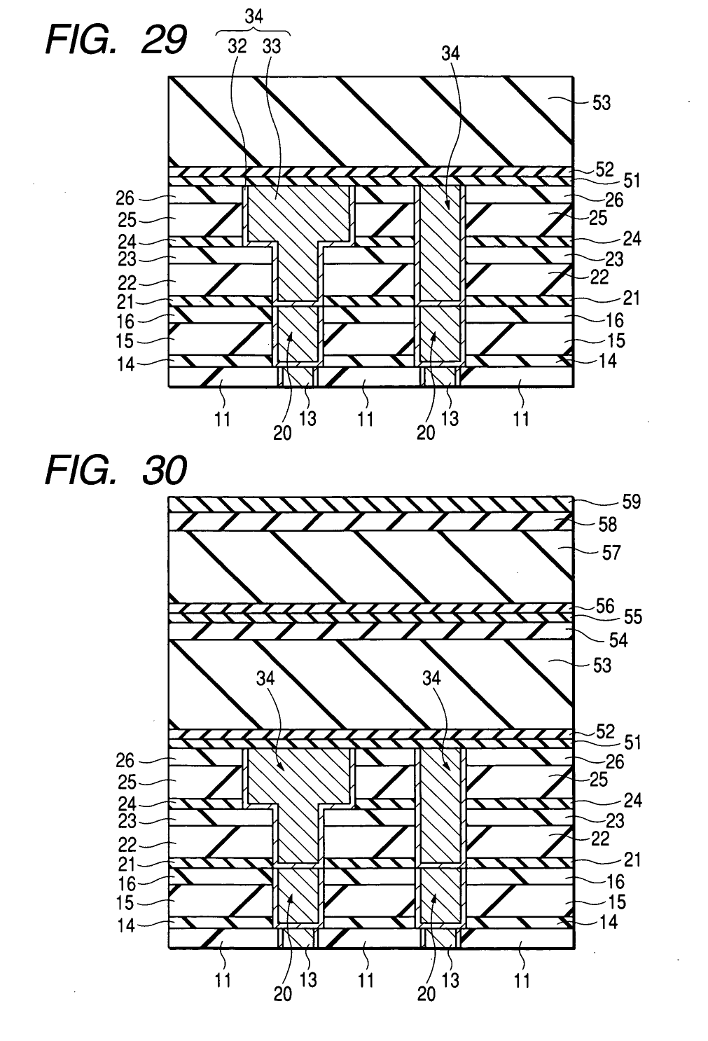

After that, as shown in FIG. 29, an insulating film (inter-layer insulating film) 53 is formed on the insulating film 52. The same material as that of the insulating film 22, that is, a fluorine (F) containing silicon oxide film (SiOF film) insulating film 53 here is used to form the insulating film 53. And, the HDP-CVD method or the like is used to form the insulating film 53. Because such an SiOF film of which permittivity is (lower than that of the silicon oxide) is used to form the insulating film 53, the total permittivity of the wirings of the semiconductor device is lowered, thereby the wiring delay of the semiconductor device is reduced. The insulating film 53 is comparatively thick, for example, about 400 to 800 nm in thickness.

In the deposition process of the insulating film 53 comprising an SiOF film, a no-oxygen containing gas (ex., an inactive gas of argon) is used to generate the heat-up plasma just like the deposition process of the insulating film 22 in the first embodiment, then the semiconductor substrate 1 is heated up to a predetermined deposition temperature with the heat-up plasma. After that, predetermined deposition gases (an SiH₄ gas, an SiF₄ gas, an O₂ gas, and an Ar gas) are introduced into the deposition chamber to deposit the SiOF film (insulating film 53). And, because an insulating film 52 comprising silicon oxide or silicon oxide nitride is already formed on the insulating film 51 comprising silicon carbide nitride to function as a protection film of the insulating film 51, the insulating film 51 is never oxidized even when the heat-up plasma includes oxygen plasma. In the deposition process of the insulating film 53, therefore, the heat-up plasma generated by an oxygen-containing gas (ex., a mixture of an argon gas and oxygen) can be used.

The F (fluorine) separated from the insulating film 53 comprising an SiOF film and the HF (hydrogen fluoride) generated by the F are trapped or caught by the insulating film 52. The insulating film 52 comprising a silicon oxide film or silicon oxide nitride film formed by the plasma CVD method as described above is strong in bonding property, so that it hardly generates Si—F bonds, etc (Si—O bonds are kept as are). Consequently, the adhesive strength that functions between the insulating films 53 and 52 is never degraded by the F and HF separated from the insulating film 53. In addition, the insulating film 52 comprising a silicon oxide film or silicon oxide nitride film formed by the plasma CVD method as described above is comparatively high in density (more than the oxide film formed when the surface of the insulating film 51 is oxidized) and has comparatively less cavities therein. The insulating film 52 functions effectively to prevent diffusion of F and HF from the insulating film 53 into the insulating film 51. At the surface boundary between the insulating films 52 and 51, therefore, such bonds as Si—F never occur. The adhesive strength that functions between the insulating films 52 and 51 is never degraded by the F and HF separated from the insulating film 53, thereby a high adhesive strength is assured between the insulating films 51 and 52, as well as between the insulating films 52 and 53. This is why the insulating film 53 is prevented from delamination from its adjacent insulating film.

In order to obtain such an effect (delamination preventive effect), the insulating film 52 should desirably be 25 nm and over in thickness. If not, the above effect is reduced. If the insulating film 52 is excessively thick (ex., 100 nm and over), the inter-wiring capacity increases. This is why the insulating film 52 should desirably be within 25 to 100 nm.

After that, as shown in FIG. 30, an insulating film 54 is formed on the insulating film 53. The insulating film 54 comes to comprise the same material as that of the insulating film 23, for example, a silicon oxide film (SiOₓ film) or silicon oxide nitride (SiON) film here. The insulating film 54 can prevent diffusion of fluorine in the insulating film 53. The insulating film 54 is about 50 to 200 in thickness.

After that, an insulating film (etching stopper film) 55 is formed on the insulating film 54. The insulating film 55 comes to comprise the same material as that of the insulating film 24, for example, a silicon carbide nitride (SiCN) film. The insulating film 55 may also be formed of another material, for example, a silicon carbide (SiC) film or silicon oxide carbide (SiOC) film. The insulating film 55 is about 10 to 50 nm in thickness.

After that, an insulating film 56 is formed on the insulating film 55. The insulating film 56 can be formed of the same material using the same method as those of the insulating film 52. For example, the insulating film 56 may comprise a silicon oxide (SiOₓ) film or silicon oxide nitride (SiON) film. The insulating film 56 should desirably be within 25 to 100 nm just like the insulating film 52. After that, an insulating film (inter-layer insulating film) 57 is formed on the insulating film 56 and an insulating film 58 is formed on the insulating film 57 respectively. The insulating film 57 comes to comprise the same material as that of the insulating film 25, for example, a silicon oxide film containing fluorine (F) (SiOF) here. The insulating film 57 is comparatively thick, for example, 300 to 600 nm. The insulating film (SiOF film) 57 can be formed using the same method as that of the insulating film 53. The insulating film 58 comes to comprise the same material as that of the insulating film 26, for example, a silicon oxide film (SiOₓ film) or silicon oxide nitride (SiON) film and can prevent diffusion of fluorine in the insulating film 57. The insulating film 58 is about 50 to 200 nm in thickness. The insulating film 56 formed between the insulating films 55 and 57 can prevent diffusion of F and HF from the insulating film 57 into the insulating film 55, as well as prevent delamination of the insulating film 57 from itself just like the insulating film 52.

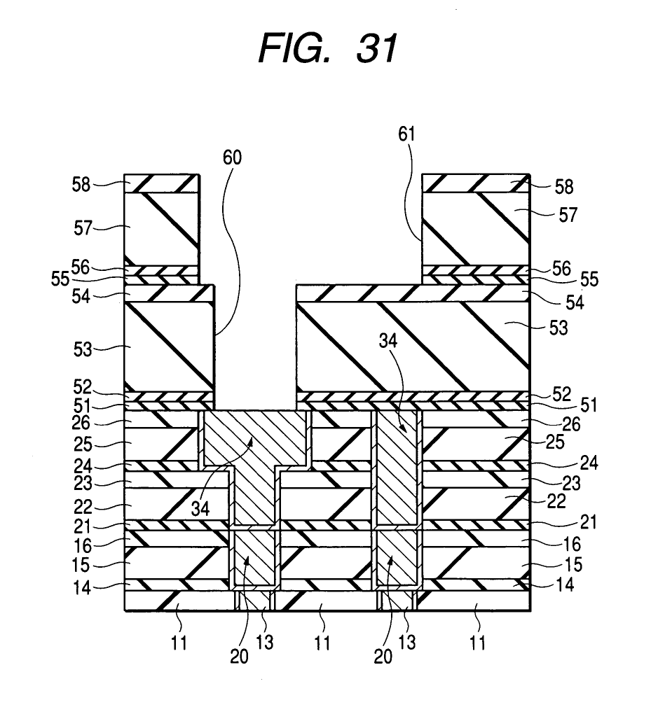

After that, an insulating film (hard mask layer) 59 is formed on the insulating film 58. The insulating film 59 comes to comprise, for example, a silicon nitride film or the like. After that, the insulating films 53 to 59 are removed selectively in the same processes as those (for forming apertures 29 and 31) shown in FIGS. 10 through 17 in the first embodiment so as to form the apertures (via holes) 60 and (wiring grooves) 61 as shown in FIG. 31. Then, the insulating film 51 at the bottom of each aperture 60 and the insulating film 55 at the bottom of each aperture 61 are removed through dry-etching or the like to form wiring aperture part comprising apertures 60 and 61. The insulating film 59 can be removed in any of this dry-etching process or another dry-etching process to be performed later. As a result, the structure shown in FIG. 31 is obtained.

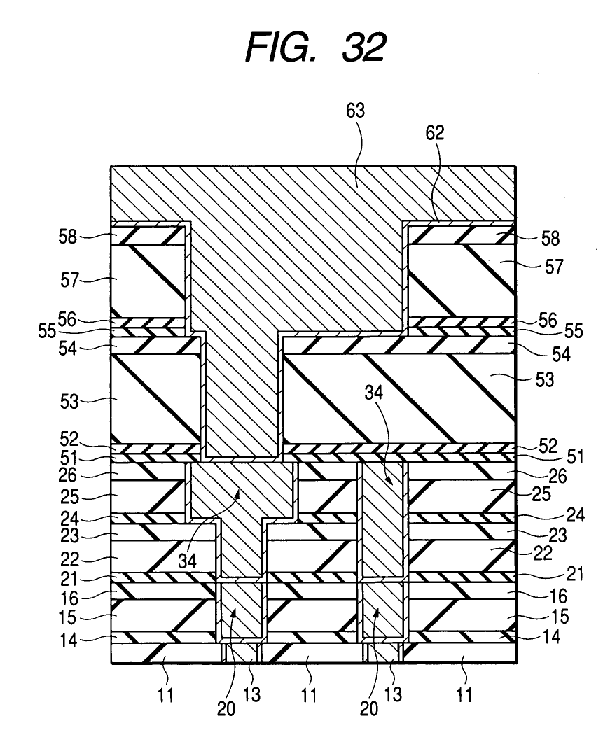

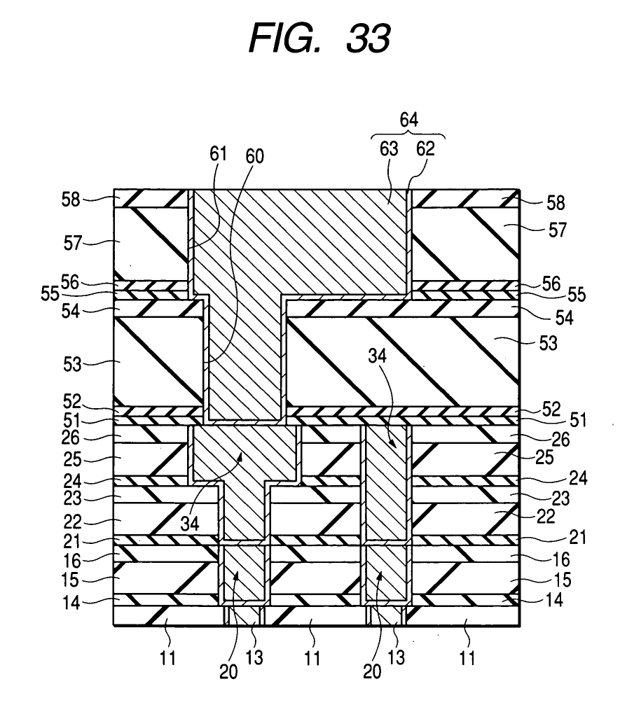

After that, as shown in FIG. 32, a conductive barrier film 62 is formed all over the main surface of the semiconductor substrate 1 (that is, on the insulating film 58 that includes the bottoms and side walls of the apertures 60 and 61) using the same method and material as those of the conductive barrier film 32. Then, a main conductive film 63 is formed using the same material and method as those of the main conductive film 33 on the conductive barrier film 62 so as to fill up the apertures 60 and 61. Then, as shown in FIG. 33, wiring (the third layer wiring) 64 comprising apertures 60 and 61 is formed by polishing the main conductive film 63 and the conductive barrier film 62 until the top surface of the insulating film 58 is exposed, for example, using the CMP method. The wiring 64 includes a conductive barrier film 62 that is comparatively thin and a main conductive film 63 that is comparatively thick and connected electrically to the wiring 34. The apertures 61 correspond to the wiring grooves while the apertures 60 correspond to holes or via holes used for the connection between the upper layer wiring (wiring 64) and the lower layer wiring (wiring 34). Consequently, the conductive portions (the conductive barrier film 62 and the main conductive film 63) embedded in each aperture 61 correspond to wiring portions and the conductive portions (the conductive barrier film 62 and the main conductive film 63) embedded in each aperture 60 corresponds to via holes or plugs.

After that, wirings in and above the fourth layer wiring (wiring 64) can be formed by repeating the same process as that of the third layer wiring. However, the description for the wirings will be omitted here.

In this third embodiment, a silicon oxide film (or silicon oxide nitride film) is formed between an insulating film containing carbon and silicon (SiCN film, SiC film, or SiOC film) and a silicon oxide film containing fluorine (SiOF film) using the plasma CVD method or the like. Diffusion of both F and HF from the SiOF film is trapped in the silicon oxide film (or silicon oxide nitride film) so as to assure the high adhesive strength that functions among the insulating film containing carbon and silicon, the silicon oxide film (or silicon oxide nitride film), and the silicon oxide film containing fluorine, thereby the SiOF films are prevented from delamination.

If a film formed of silicon oxide containing fluorine, that is, an SiOF film is thick or high in fluorine density (fluorine content), diffusion of F and HF from the SiOF film into the lower layer is often accelerated to separate the SiOF film from the lower layer. In this embodiment, however, because the SiOF film is prevented from delamination very effectively, the manufacturing method will be effective for a multi-layer structure that is apt to cause such SiOF film delamination (if the SiOF film is thick and high in fluorine density).

Furthermore, the number of manufacturing processes increases when compared with the first embodiment described above although forming a silicon oxide film (or silicon oxide nitride film) under an SiOF film just like in this third embodiment is effective significantly to prevent delamination of the SiOF film. Consequently, if an SiOF film is comparatively thin or its fluorine density (fluorine content) is comparatively low, the SiOF film is not delaminated easily from the lower layer. It is thus possible to deposit each SiOF film with the heat-up plasma generated by a gas containing no oxygen without forming any silicon oxide film under the SiOF film just like in the first embodiment. On the other hand, if the SiOF film is comparatively thick and its fluorine density is comparatively high, the SiOF film is apt to be delaminated. Therefore, a silicon oxide film (or silicon oxide nitride film) maybe formed under an SiOF film just like in this third embodiment.

For example, if the SiOF film is 600 nm and over, the method in the first embodiment (for depositing an SiOF film with the heat-up plasma generated by a gas containing no oxygen). In that connection, the SiOF films (insulating films 53 and 57) formed by the method in this third embodiment come to become thicker than the SiOF films (insulating films 22 and 25) formed by the method in the first embodiment.

It is more desirable if the method in this third embodiment applies to a case in which the fluorine density in the SiOF film is 1.4×10²¹ atms/cm³ (or 5% at a bonding ratio of Si—F/Si—O) and over and the method in the first embodiment applies to a case in which the fluorine density in the SiOF film is 1.4×10²¹ atms/cm³ (or 5% at a bonding ratio of Si—F/Si—O) and under.

That makes it possible to suppress the number of manufacturing processes of the semiconductor device from increasing and prevent the SiOF film from separating effectively. The reliability of the semiconductor device is thus improved and the manufacturing cost thereof is reduced.

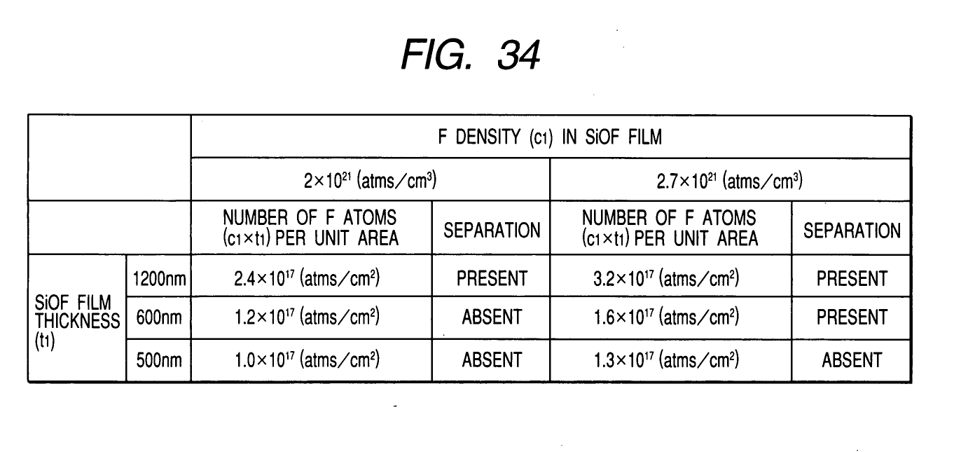

FIG. 34 shows a table for denoting how the SiOF film is delaminated when the method in the first embodiment is used to form the SiOF film. Concretely, the table shown in FIG. 34 denotes test results obtained by checking whether or not the SiOF film is delaminated by changing the SiOF film thickness to 500 nm, 600 nm, and 1200 nm after the SiOF film is formed by the method in the first embodiment; the fluorine (F) density (c1) in the SiOF film is assumed as two types (2.0×10²¹ atms/cm³ and 2.7×10²¹ atms/cm³) here.

As shown clearly in FIG. 34, if the product of the film thickness t1 and the fluorine density c1 (c1×t1, that is, when the number of fluorine (F) atoms per unit area is less than 1.5×10¹⁷ (atms/cm²) (for example, film thickness 500(nm)×fluorine density 2.7×10²¹ (atms/cm³)=1.3×10¹⁷ (atms/cm²)) while the thickness of the SiOF film is assumed as t1 and the fluorine density in the SiOF film is assumed as c1 (atms/cm³), the method in the first embodiment is effective to prevent the SiOF film from delamination. However, if the product of the film thickness t1 and the fluorine density c1 (c1×t1, that is, when the number of fluorine (F) atoms per unit area is greater than 1.5×10¹⁷ (atms/cm²) (for example, film thickness 600(nm)×fluorine density 2.7×10²¹ (atms/cm³)=1.6×10¹⁷ (atms/cm²)), the method in the first embodiment causes delamination of the SiOF film (film delamination: recognized).

Consequently, if the product of the film thickness t1 and the fluorine density c1 (c1×t1) is 1.5×10¹⁷ (atms/cm²) and over while the thickness of the SiOF film is assumed as t1 and the fluorine density in the SiOF film is assumed as c1 (atms/cm³), the method in this third embodiment that can prevent the SiOF film from delamination more effectively should desirably apply to form the SiOF film. On the other hand, if the product of the film thickness t1 and the fluorine density c1 (c1×t1) is 1.5×10¹⁷ (atms/cm²) and under, the method in the first embodiment should desirably apply to the SiOF film.

Consequently, the number of manufacturing processes of the semiconductor device is prevented from increasing and the SiOF film is prevented from delamination effectively. The reliability of the semiconductor device is thus improved and the manufacturing cost thereof is reduced.

Furthermore, as shown in FIG. 33, the upper layer wiring has wiring via holes thicker and deeper than those of the lower layer wiring. Consequently, each SiOF film used as an inter-layer insulating film (inter-wiring insulating film or inter-via insulating film) is apt to become thicker in the upper layer wiring than the lower layer wiring. This is why the heat-up plasma generated by a no-oxygen containing gas is used to form each SiOF film (insulating films 15, 22, and 25) in the deposition processes of the lower layer wiring (for example, the first layer wiring (wiring 20) and the second layer wiring (wiring 34)) like the first embodiment while a silicon oxide film (or silicon oxide nitride film) is formed under each SiOF film (insulating films 53 and 57) like this third embodiment in the deposition processes of the upper layer wirings (for example, the third (wiring 64) and upper layer wirings). This prevents the number of manufacturing processes of the semiconductor device from increasing and the SiOF film from delamination effectively. The reliability of the semiconductor device is thus improved and the manufacturing cost thereof is reduced.

Fourth Embodiment

In the first to third embodiments, how to form an embedded copper wiring has been described. In this fourth embodiment, however, how to form aluminum wirings will be described.

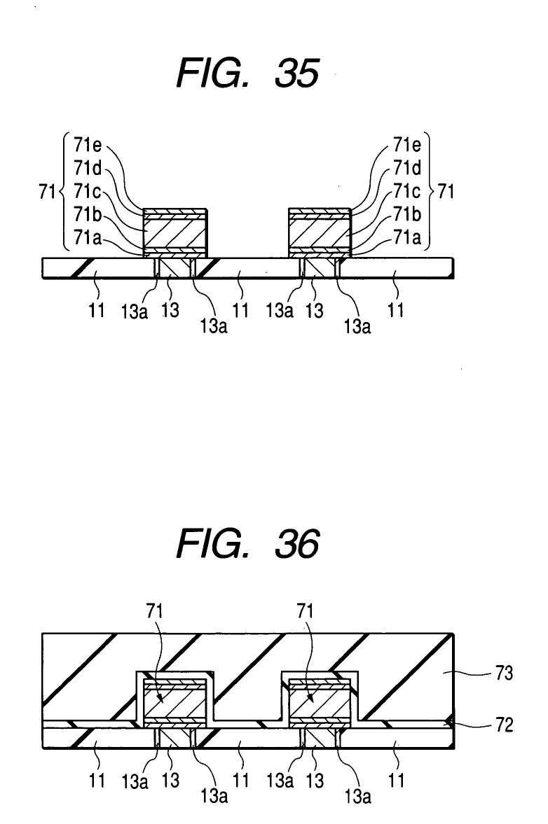

FIGS. 35 through 42 show cross sectional views of a semiconductor device in manufacturing processes in this fourth embodiment. In order to simplify the description, the structure of the semiconductor device corresponding to the structure thereof under the insulating film shown in FIG. 1 will be omitted here. And, because the manufacturing processes up to those shown in FIG. 1 are the same as those in the first embodiment, the description for them will be omitted here; only the processes that follow those shown in FIG. 1 will be described.

After obtaining the structure shown in FIG. 1, wirings (aluminum wiring) 71 are formed as shown in FIG. 35. For example, they are formed all over the semiconductor substrate 1, that is, on the insulating film 11 in which the plugs 13 are embedded; concretely a refractory metal film such as a titanium film 71a, a refractory metal nitride film such as a titanium nitride film 71b, a conductive film comprising mainly aluminum such as aluminum alone or aluminum alloy, that is, an aluminum film 71c, a refractory metal film such as a titanium film 71d, and a refractory metal nitride film such as a titanium nitride film 71e are formed on the substrate 1 in order. Then, those films are patterned by, for example, the photo-lithography method and the dry-etching method to form the wirings 71. The formed wirings 71 are connected to an n⁺ type semiconductor region (source or drain) 8 and a gate electrode 5 electrically through plugs 13.

After that, as shown in FIG. 36, a relatively thin insulating film 72 is formed on the insulating film 11 so as to cover the wirings 71. The insulating film 72 comes to comprise, for example, a silicon oxide film or the like. Then, an insulating film 73 is formed on the insulating film 72 so as to fill up each space between wirings 71. The insulating film 73 comes to comprise a low permittivity insulating material, for example, MSQ, HSQ, or organic polymer (including their porous materials). A coating method can be used to form the insulating film 73. If the insulating film 73 comprises HSQ, forming of the insulating film 72 may be omitted.

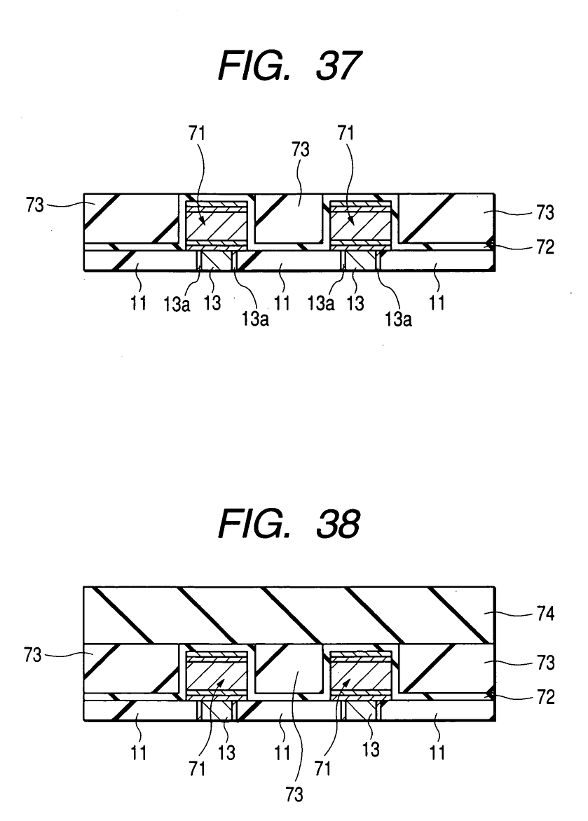

After that, as shown in FIG. 37, the insulating film 73 is flattened by an etching-back method or CMP method. Consequently, the insulating film 72 on the top surface of each wiring 71 is exposed. Then, as shown in FIG. 38, an insulating film 74 is formed all over the semiconductor substrate 1 (on the insulating film 73 including the surface of the exposed insulating film 72). The insulating film 74 comes to comprise, for example, a fluorine containing silicon oxide (SiOF) film. The insulating film 74 may also be formed of another material, for example, a silicon oxide carbide (SiOC) film. In the deposition process of the insulating film 74, the surface of the insulating film 73 might be oxidized, causing the insulating films 74 and 73 to be delaminated from each other.

In this fourth embodiment, if the insulating film 74 is to comprise an SiOF film, the insulating film (SiOG film) 74 is formed just like the insulating film (SiOF film) 22 in the first embodiment. In other words, the semiconductor substrate 1 is heated up to a predetermined deposition temperature by the heat-up plasma generated by a gas containing no oxygen (ex., an inactive gas of argon), then the insulating film 74 comprising an SiOF film is deposited on the insulating film 73 by the HDP-CVD method. Consequently, the surface of the insulating film 73 is suppressed or prevented from oxidization, thereby the adhesion (adhesive strength) that functions between the insulating films 74 and 73 is improved and the insulating films 74 and 73 are prevented from delamination.

If the insulating film 74 is to comprise an SiOF film, a plasma treatment is applied to the semiconductor substrate 1 with the heat-up plasma generated by an inactive gas before forming the insulating film (SiOF film) 74 just like the treatment performed before forming the insulating film (SiOF film) 22a. In other words, the insulating film 73 is etched back or flattened by the CMP method, then a plasma treatment is applied to the semiconductor substrate 1 with the heat-up plasma generated by an inactive gas before forming the insulating film 74. The plasma treatment may be a helium plasma treatment, for example. Consequently, the surface of the insulating film 73 is prevented from absorption of the moisture content. The adhesion (adhesive strength) that functions between the insulating films 74 and 73 is thus improved and the insulating films 74 and 73 are prevented from delamination.

In the second embodiment, a description is made for a possibility that the adhesion (adhesive strength) that functions between upper and lower insulating films is improved, thereby those insulating films are prevented from delamination if a plasma treatment is applied on the surface of the lower insulating film (insulating film 21) with the heat-up plasma generated by an inactive gas (ex., helium plasma treatment) before forming the upper insulating film (insulating film 22a) even when the upper insulating film (insulating film 22a) comprising HSQ, MSQ, or organic polymer (including their porous materials) is formed on the lower insulating film (insulating film 21) comprising a material film containing carbon (C) (and silicon (Si)) (ex., a silicon carbide nitride (SiCN) film, silicon carbide (SiC) film, or silicon oxide carbide (SiOC) film). If the lower and upper insulating films are exchanged, that is, if the upper insulating film (insulating film 74) comprising a material film (ex., a silicon oxide carbide (SiOC) film, silicon carbide (SiC) film, or silicon carbide nitride (SiCN) film) is formed on the lower insulating film (insulating film 73) comprising HSQ, MSQ, or organic polymer (including their porous materials) just like in this fourth embodiment, the surface of the lower insulating film is prevented from absorption of the moisture content by applying a plasma treatment on the surface of the lower insulating film (insulating film 73 with the heat-up plasma generated by an inactive gas (ex., helium plasma treatment) before forming the upper film (insulating film 74). As a result, the adhesion (adhesive strength) that functions between upper and lower insulating films is improved, thereby those insulating films are prevented from delamination. In addition, even when a material film containing carbon (C) such as a photo-resist film (reflection preventive film) or the like is formed on an insulating film comprising HSQ, MSQ, or organic polymer (including their porous materials), if a plasma treatment is applied on the surface of the insulating film with the heat-up plasma generated by an inactive gas (ex., helium plasma treatment) before forming the photo-resist film (reflection preventive film) on the insulating film, the photo-resist film (reflection preventive film) is prevented from delamination without fail.

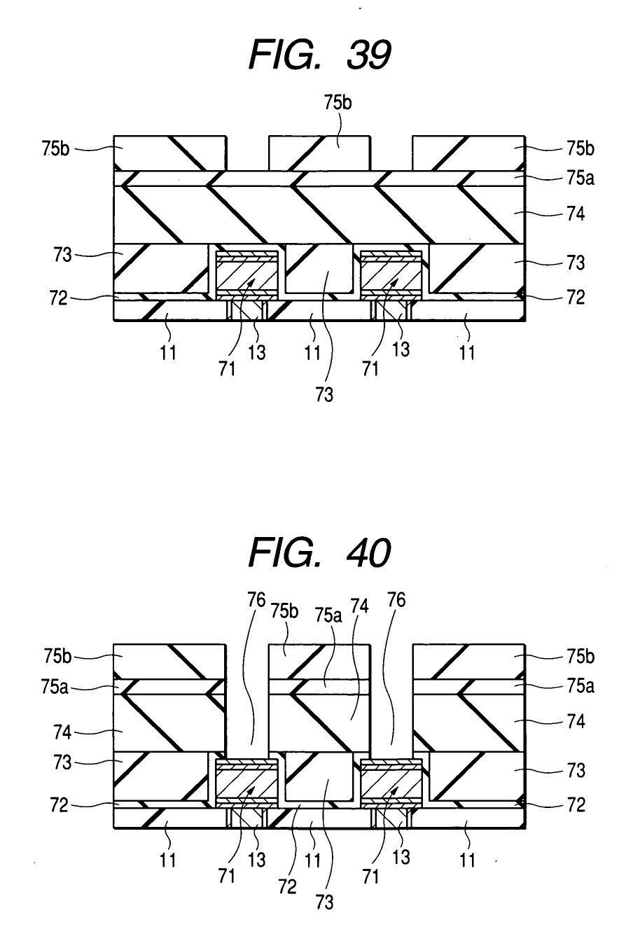

After that, as shown in FIG. 39, a reflection preventive film 75a is formed on the insulating film 74. Then, a photo-resist film is formed on the reflection preventive film 75a and the photo-resist film is patterned by exposure or the like to form a photo-resist pattern 75b. Apertures are formed in a flat area of the photo-resist pattern 75b, in which via holes are to be formed.

After that, as shown in FIG. 40, the reflection protective film 75a is removed selectively by the dry-etching method using the photo-resist pattern 75b as an etching mask. Then, the insulating films 74 and 73 are removed selectively by the dry-etching method using the photo-resist pattern 75b as an etching mask to form apertures (via holes) 76. The apertures (via holes) 76 are formed in a flat region (position) in which via holes are to be formed.

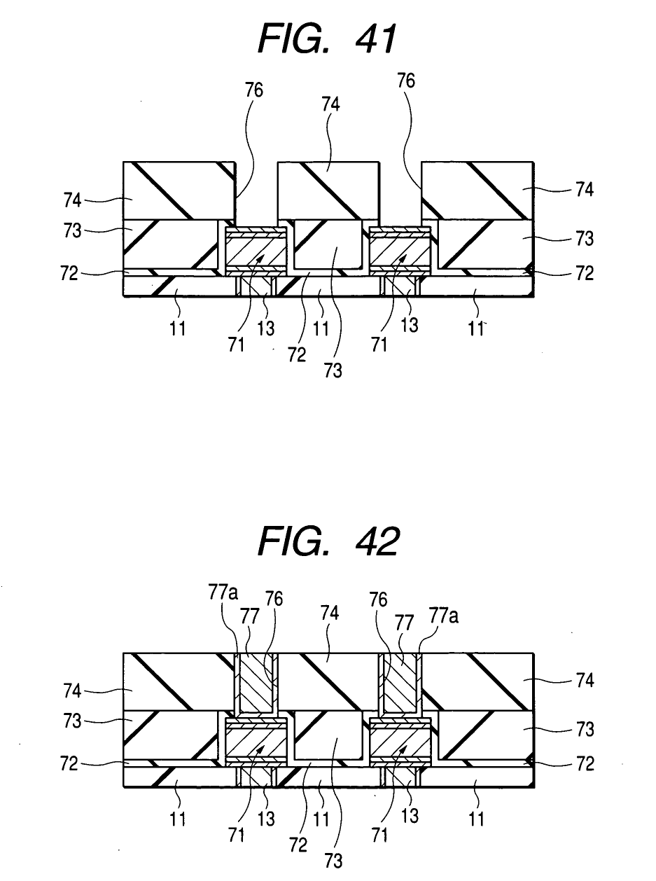

After that, as shown in FIG. 41, both of the residual photo-resist pattern 75b and the residual reflection preventive film 75a are removed by ashing or the like.

After that, as shown in FIG. 42, a plug 77 is formed of tungsten (W) in each aperture 76. Concretely, the plug 77 is formed, for example, by forming a titanium nitride film 77a as a barrier film on the insulating film 74 that includes the inner portion of each aperture 76, then forming a tungsten film on the titanium nitride film 77a by the CVD method or the like so as to fill up the aperture 76, then removing unnecessary portions of both tungsten film and titanium nitride film 77a from the insulating film 74 by the CMP method or etching-back method. The plug 77 is connected electrically to the wirings 71.

After that, upper layer wiring is formed on the insulating film 74 in which the plugs 77 are embedded just like the wiring 71. The upper layer wiring is connected electrically to the plugs 77. Both illustration and description for the upper layer wiring will be omitted here.

Also in this fourth embodiment, the adhesion (adhesive strength) that functions between insulating films is improved just like the above embodiments. Consequently, just like any of the semiconductor devices having copper wirings in the above embodiments, even the semiconductor device having aluminum wirings can use low permittivity insulating films, thereby reducing the inter-wiring capacity, preventing delamination of a film from another, and improving the reliability of the semiconductor device.

Fifth Embodiment

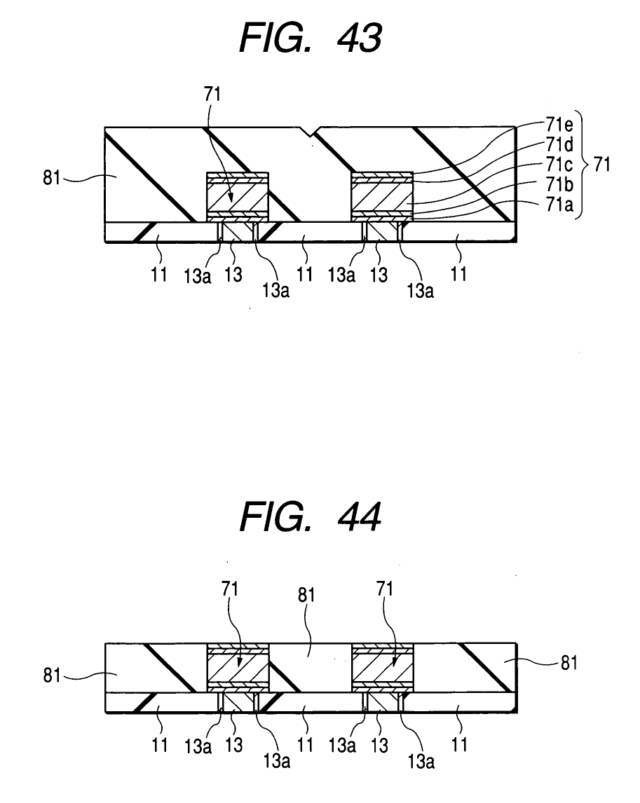

FIGS. 43 to 46 show cross sectional views of major portions of a semiconductor device in manufacturing processes in the fifth embodiment of the present invention. In order to simplify the description, the structure of the semiconductor under the insulating film 11 shown in FIG. 1 is omitted in FIGS. 43 through 46. And, because the manufacturing processes shown in up to FIG. 35 are the same as those in the fourth embodiment, the description for them will be omitted here; only the processes that follow those shown in FIG. 35 will be described below.

After obtaining the structure shown in FIG. 35, as shown in FIG. 43, an insulating film 81 is formed on the insulating film 11 so as to cover the wirings 71. The insulating film 81 comes to comprise, for example, a silicon oxide carbide (SiOC) film or the like. The CVD method can be used to form the insulating film 81.

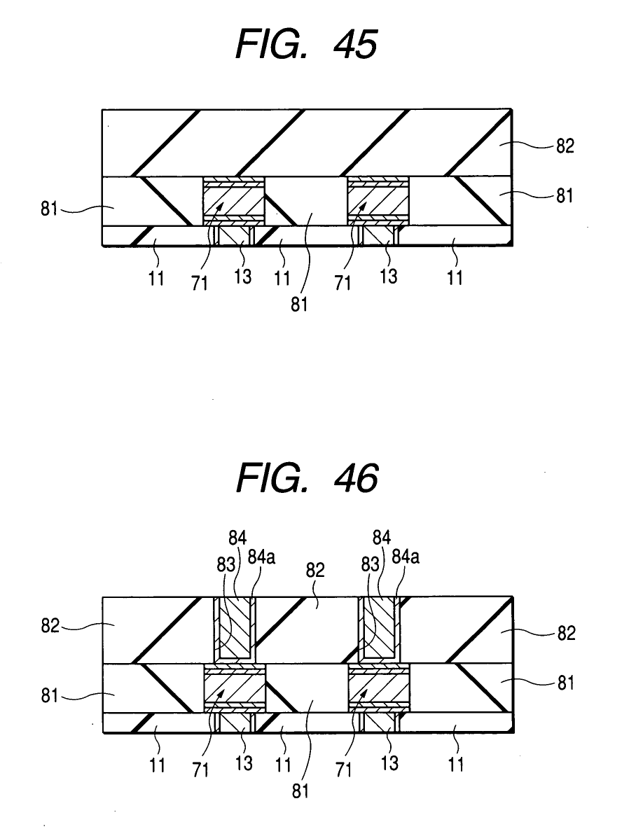

After that, as shown in FIG. 44, the insulating film 81 is etched back or flattened by the CMP method or the like. The top surface of the wiring 71 is thus exposed. After that, as shown in FIG. 45, an insulating film 82 is formed all over the semiconductor substrate 1 (on the insulating film 81 that includes the top surface of each wiring 71). The insulating film 82 comes to comprise, for example, a fluorine containing silicon oxide (SiOF) film. In the deposition process of the insulating film 82, however, a problem might occur; the surface of the insulating film is oxidized, thereby the insulating films 81 and 82 are delaminated from each other.

In this fifth embodiment, if the insulating film 82 is to comprise an SiOF film, the film (SiOF film) 82 is formed just like the insulating film (SiOF film) 22 in the first embodiment. Concretely, the semiconductor substrate 1 is heated up to a predetermined deposition temperature by the heat-up plasma generated by a gas containing no oxygen (ex., an inactive gas of argon), then the insulating film that is to comprise an SiOF film is formed on the insulating film 81 using the HDP-CVD method. Consequently, the insulating film 81 is suppressed or prevented from oxidization that might occur on its surface, thereby the adhesion (adhesive strength) that functions between the insulating films 82 and 81 is improved. The insulating films 82 and 81 is thus prevented from delamination.

After that, just like in the fourth embodiment described above, as shown in FIG. 46, apertures (via holes) 83 are formed in the insulating film 82 to expose the wiring 71 at the bottom of each aperture by the photo-lithography method and the etching method. Then, a plug 84 is formed so as to fill up each aperture 83. Each aperture 83 can be formed almost like the aperture 76 in the fourth embodiment. Just like the plug 77 in the fourth embodiment, the plug 84 is formed by forming a titanium nitride film 84a on the insulating film 82 that includes the inner portion of the aperture 83 as a barrier film, then forming a tungsten film on the titanium nitride film 84a by the CVD method so as to fill up the aperture 83, then removing unnecessary portions of both tungsten film and titanium nitride film 84a from the insulating film 82 by the CMP method or etching-back method. The plug 84 is connected electrically to its corresponding wiring 71.

After that, upper layer wiring is formed on the insulating film 82 in which the plugs 84 are embedded, just like the wiring 71. The upper layer wiring is connected to the plugs 84 electrically. The upper layer wiring is not illustrated nor described here, however.

Also in this fifth embodiment, it is possible to improve the adhesion (adhesive strength) that functions between insulating films just like the above embodiments. Therefore, even in the semiconductor device having aluminum wirings, low permittivity insulating films can be used to reduce the inter-wiring capacity, prevent insulating films from delamination, and improve the reliability of the semiconductor device.

Sixth Embodiment

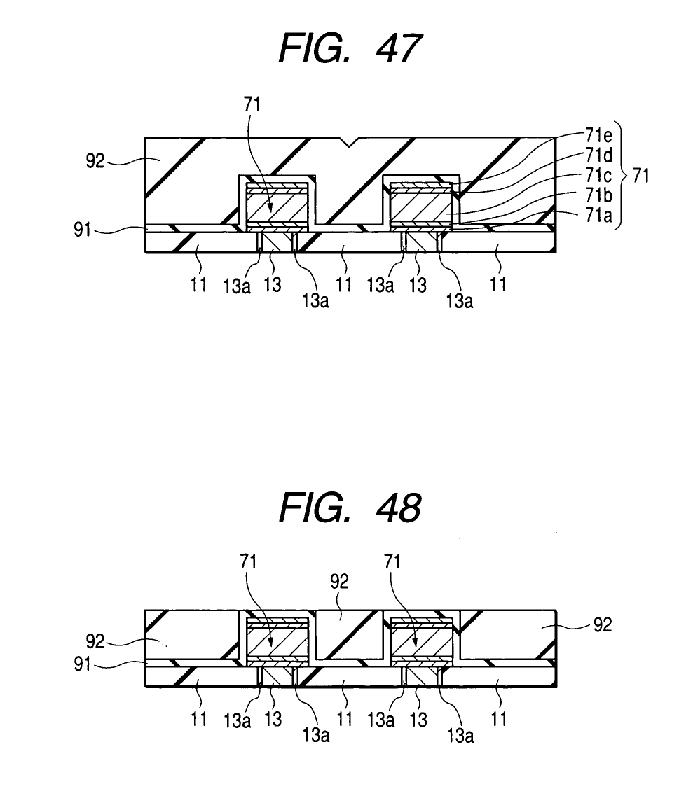

FIGS. 47 through 50 show cross sectional views of a semiconductor device in manufacturing processes in the sixth embodiment of the present invention. In order to simplify the description, the structure of the semiconductor device under the insulating film 11 shown in FIG. 1 is omitted here. And, the manufacturing processes shown in up to FIG. 35 are the same as those in the fourth embodiment described above, so that the description for them will be omitted here; only the processes that follow those shown in FIG. 35 will be described below.

After obtaining the structure shown in FIG. 35, as shown in FIG. 47, a relatively thin insulating film 91 is formed on the insulating film 11 so as to cover the wirings 71. The insulating film 91 comes to comprise, for example, a silicon carbide (SiC) film or silicon oxide nitride (SiON) film. The CVD method or the like can be used to form the insulating film 91. After that, an insulating film 92 is formed on the insulating film 91 so as to fill up each space between wirings 71. The insulating film 92 comes to comprise, for example, a silicon oxide carbide (SiOC) film that is formed by the CVD method. And, if an insulating film 91 comprising a silicon carbide (SiC) film or silicon oxide nitride (SiON) film is formed (inserted) between each wiring (aluminum wiring) 71 and the insulating film 92 comprising a silicon oxide carbide (SiOC) film, the adhesion (adhesive strength) that functions between the wiring (aluminum wiring) 71 and the insulating film (silicon oxide nitride film) 92 is improved.

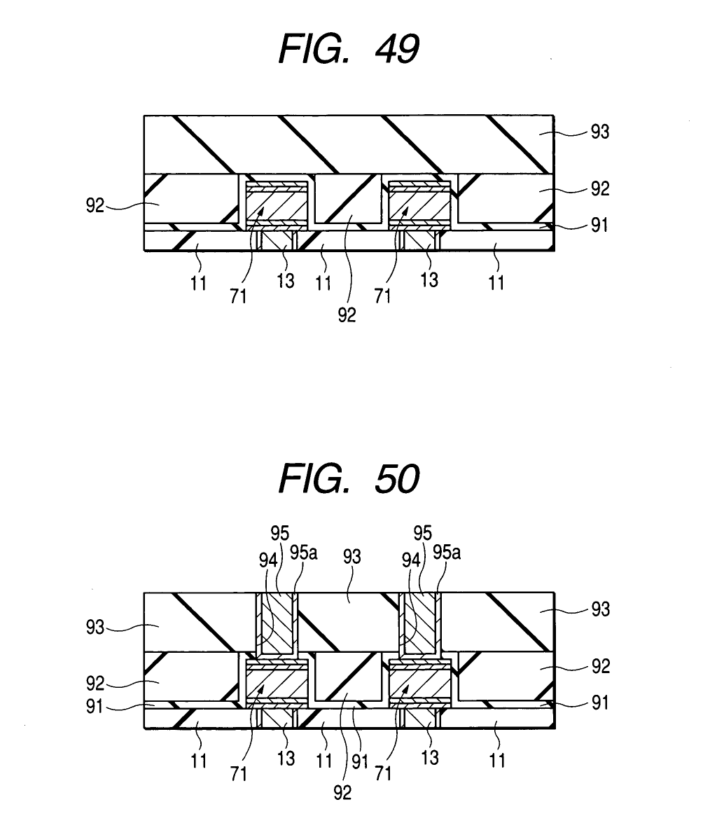

After that, as shown in FIG. 48, the insulating film 92 is flattened by the etching-back or CMP method. Consequently, the insulating film 92 formed on the top surface of each wiring 71 is exposed. Then, as shown in FIG. 49, an insulating film 93 is formed all over the semiconductor substrate 1 (on the insulating film 92 that includes the surface of the exposed insulating film 91). The insulating film 93 comes to comprise, for example, a fluorine containing silicon oxide (SiOF) film. However, the insulating films 92 and 93 might be delaminated due to the oxidization that might occur on the surface of the insulating film 92 in the deposition process of the insulating film 93.

In this sixth embodiment, if the insulating film 93 is to comprise an SiOF film, the insulating film (SiOF film) 93 is formed just like the insulating film (SiOF film) 22 in the first embodiment. Concretely, the semiconductor substrate 1 is heated up to a predetermined deposition temperature by the heat-up plasma generated by a gas containing no oxygen (ex., an inactive gas of argon), then the insulating film 93 that is to comprise an SiOF film is deposited by the HDP-CVD method on the insulating film 92 (including the surface of the exposed insulating film 91). Consequently, the surface of the insulating film 92 is suppressed or prevented from oxidization, thereby the adhesion (adhesive strength) that functions between the insulating films 92 and 93 is improved and the insulating films 92 and 93 are prevented from delamination.

After that, just like the fourth embodiment described above, as shown in FIG. 50, apertures (via holes) 94 are formed in the insulating film 93 by the photo-lithography method and the etching method, then plugs 95 that are to embed the apertures 94 are formed. At the bottom of each aperture 94 is exposed the wiring 71. The apertures can be formed almost like the apertures 76 in the fourth embodiment. The plugs 95 can be formed just like the flags 77 in the fourth embodiment. Concretely, each plug 95 is formed by forming, for example, a titanium nitride film 95a on the insulating film 93 that has the inner portion of each aperture 94 as a barrier film, then forming a tungsten film on the titanium nitride film 95a by the CVD method so as to fill up the apertures 94, then removing unnecessary portions of both tungsten film and titanium nitride film 95a from the insulating film 94 by the CMP method or etching-back method. Each plug 95 is connected electrically to the corresponding wiring 71.

After that, upper layer wiring is formed on the insulating film 93 in which plugs 95 are embedded, just like the wirings 71. The upper layer wiring is connected to the plugs 95 electrically. However, the wiring is not illustrated nor described here.

Also in this sixth embodiment, just like the above embodiments, the adhesion (adhesive strength) that functions between insulating films, as well as the adhesion (adhesive strength) that functions between each wiring (aluminum wiring) and each insulating film is improved. Consequently, even a semiconductor device having aluminum wirings can use low permittivity insulating films to reduce the inter-wiring capacity, prevent each of the film from delamination from another, and improve the reliability.

While the preferred form of the present invention has been described on the basis of the embodiments, it is to be understood that modifications will be apparent to those skilled in the art without departing from the spirit of the invention.

While a description has been made for a semiconductor device having a MISFET therein in the above embodiments, the present invention may also apply to other various semiconductors.

The typical effects obtained by the present invention disclosed in this specification will be summarized as follows.

The adhesion (adhesive strength) that functions between films can be improved by heating the semiconductor substrate up to a predetermined deposition temperature with a heat-up plasma generated by a gas including no oxygen when in depositing an insulating film comprising a fluorine containing silicon oxide film.

The adhesion (adhesive strength) that functions between films can also be improved by forming a silicon oxide film or silicon oxide nitride film between an insulating film comprising silicon and carbon and a fluorine containing silicon oxide film formed on the insulating film.

What is claimed is:

1. A method for manufacturing a semiconductor device, comprising the steps of:
(a) preparing a semiconductor substrate;
(b) forming a first insulating film comprising a material containing silicon and carbon on said semiconductor substrate; and
(c) forming a second insulating film comprising fluorine-containing silicon oxide on said first insulating film;
wherein said semiconductor substrate is heated up to a deposition temperature of said second insulating film with plasma generated by a gas that includes no oxygen in said step (c).

2. The method according to claim 1,
wherein a high density plasma CVD method is used to form said second insulating film in said step (c).

3. The method according to claim 1,
wherein said first insulating film comprises a silicon carbide film, silicon nitride carbide film, or silicon oxide carbide film.

4. The method according to claim 1,
wherein plasma generated by an inactive gas is used to heat said semiconductor substrate up to the film deposition temperature of said second insulating film in said step (c).

5. The method according to claim 1,
wherein argon plasma is used to heat said semiconductor substrate up to the film deposition temperature of said second insulating film in said step (c)

6. The method according to claim 1,
wherein a film deposition gas of said second insulating film is introduced into a film deposition chamber after said semiconductor substrate is heated up to the film deposition temperature of said second insulating film in said step (c).

7. A method for manufacturing a semiconductor device, comprising the steps of:
(a) preparing a semiconductor substrate;
(b) forming a first insulating film comprising HSQ, MSQ, or organic polymer on said semiconductor substrate; and
(c) forming a second insulating film comprising silicon oxide including fluorine on said first insulating film;
wherein plasma generated by a gas containing no oxygen is used to heat said semiconductor substrate up to a film deposition temperature of said second insulating film in said step (c).

8. The method according to claim 7,
wherein a high density plasma CVD method is used to form said second insulating film in said step (c).

9. A method for manufacturing a semiconductor device, comprising the steps of:
(a) preparing a semiconductor substrate;
(b) forming a first insulating film comprising a material that includes silicon and carbon on said semiconductor substrate;
(c) applying a plasma treatment with plasma generated by an inactive gas after said step (b); and
(d) forming a second insulating film comprising silicon oxide that contains fluorine, HSQ, MSQ, or organic polymer on said first insulating film after said step (c)

10. The method according to claim 9,
wherein a helium plasma treatment is applied in said step (c).

11. The method according to claim 9,
wherein said first insulating film comprises a silicon carbide film, silicon carbide nitride film, or silicon oxide carbide film.

12. A method for manufacturing a semiconductor device, comprising the steps of:
(a) preparing a semiconductor substrate;
(b) forming a first insulating film comprising MSQ, HSQ, or organic polymer on said semiconductor substrate;
(c) applying a plasma treatment with plasma generated by an inactive gas after said step of (b); and
(d) forming a second insulating film comprising a carbon-containing material on said first insulating film after said step (c).

13. The method according to claim 12,
wherein a helium plasma treatment is applied in said step (c).

14. The method according to claim 12,
wherein said second insulating film comprises a silicon carbide film, silicon carbide nitride film, or silicon oxide carbide film.

15. A method for manufacturing a semiconductor device, comprising the steps of:
(a) preparing a semiconductor substrate;
(b) forming a first insulating film coming to comprise a material that contains silicon and carbon on said semiconductor substrate;
(c) forming a second insulating film coming to comprise silicon oxide or silicon oxide nitride on said first insulating film; and
(d) forming a third insulating film coming to comprise fluorine-containing silicon oxide on said second insulating film.

16. The method according to claim 15,
wherein a plasma CVD method is used to form said second insulating film in said step (c) and the plasma density is 1×10¹¹/cm³ and under when in forming said second insulating film.

17. The method according to claim 15,
wherein said plasma CVD method is used to form said second insulating film in said step (c) and said third insulating film in said step (d); and
wherein the plasma density in said step (c) is lower than that in said step (d).

18. The method according to claim 15,
wherein a high density plasma CVD method is used to form said third insulating film in said step (d).

19. The method according to claim 15,
wherein said first insulating film comes to comprise a silicon carbide film, a silicon carbide nitride film, or a silicon oxide carbide film.

20. The method according to claim 15,
wherein said second insulating film is 25 to 100 nm in thickness.

21. A semiconductor device, comprising:
a semiconductor substrate;
a first insulating film formed on said semiconductor substrate and comprising a material that contains silicon and carbon;
a second insulating film formed on said first insulating film and comprising silicon oxide or silicon oxide/nitride; and
a third insulating film formed on said second insulating film and comprising fluorine-containing silicon oxide.

22. The semiconductor device according to claim 21;
wherein said first insulating film comes to comprise a silicon carbide film, a silicon carbide nitride film, or a silicon oxide carbide film.

23. The semiconductor device according to claim 21;
wherein said second insulating film is within 25 to 100 nm in thickness.

24. The semiconductor device according to claim 21;
wherein said device further includes a fourth insulating film formed on said third insulating film and comprising silicon oxide or silicon oxide nitride.

25. The semiconductor device according to claim 21;
wherein said third insulating film is 600 nm and over in thickness.

26. The semiconductor device according to claim 21;
wherein the fluorine density of said third insulating film is 1.4×10²¹ atms/cm³ and over.

27. The semiconductor device according to claim 21;
wherein a product of the thickness and the fluorine density of said third insulating film is 1.5×10¹⁷ atms/cm² and over.

28. A method for manufacturing a semiconductor device having a plurality of wiring layers formed on a semiconductor substrate, said method comprising the steps of:
(a) forming a first insulating film coming to comprise a material that contains silicon and carbon on said semiconductor substrate;
(b) heating said semiconductor substrate up to a predetermined film deposition temperature with plasma generated by a gas that contains no oxygen, then forming a second insulating film coming to comprise fluorine-containing silicon oxide on said first insulating film;
wherein treatments in said steps are executed after a first wiring layer is formed on said semiconductor substrate and before a second wiring layer located just above said first wiring layer is formed; and
wherein said method further includes the steps of:
(c) forming a fourth wiring layer coming to comprise a material that contains silicon and carbon and a fourth insulating film coming to comprise silicon oxide or silicon oxide nitride on said third insulating film; and
(d) forming a fifth insulating film coming to comprise fluorine-containing silicon oxide on said fourth insulating film;
wherein treatments in said steps (c) and (d) are executed after forming said third wiring layer that is an upper wiring layer of said first wiring layer and before forming said fourth wiring layer to be located just above said third wiring layer.

29. A method for manufacturing a semiconductor device, comprising the steps:
(a) preparing a semiconductor substrate;
(b) forming a first insulating film coming to comprise a material that includes silicon and carbon on said semiconductor substrate;
(c) forming a second insulating film coming to comprise fluorine-containing silicon oxide on said first insulating film;
wherein if a product of the thickness and the fluorine density of said second insulating film is 1.5×10¹⁷ atms/cm² and under, plasma generated by a gas containing no oxygen is used in said step (c) to heat said semiconductor substrate up to a film deposition temperature of said second insulating film, then said second insulating film is formed on said first insulating film; and
wherein if said product of the thickness and the fluorine density of said second insulating film is 1.5×10¹⁷ atms/cm² and over, said third insulating film is formed of silicon oxide or silicon oxide nitride on said first insulating film after said step (b) and before said step (c) then said second insulating film is formed on said third insulating film in said step (c).
